(19) United States
(12) Patent Application Publication
(10) Pub. No.: US 2026/0206302 A1
(43) Pub. Date: Jul. 16, 2026

(54) SEMICONDUCTOR DEVICE

(71) Applicant: SAMSUNG ELECTRONICS CO., LTD., Suwon-si (KR)

(72) Inventors: Jinchan YUN, Suwon-si (KR); Jae Hyun PARK, Suwon-si (KR)

(73) Assignee: SAMSUNG ELECTRONICS CO., LTD., Suwon-si (KR)

(21) Appl. No.: 19/311,896

(22) Filed: Aug. 27, 2025

(30) Foreign Application Priority Data
Jan. 13, 2025 (KR) 10-2025-0004740

(51) Int. Cl. H10D 84/83; H10D 64/23; H10D 30/00; H10D 62/10

(52) U.S. Cl. CPC H10D 84/832; H10D 64/258; H10D 30/502; H10D 62/121

(57) ABSTRACT

A semiconductor device includes a first transistor structure including lower channel patterns, a lower source/drain pattern, a lower gate electrode surrounding the lower channel patterns, a lower bonding insulating layer on the lower source/drain pattern and the lower gate electrode, and a lower contact structure between the lower bonding insulating layer and the lower source/drain pattern. A second transistor structure includes an upper bonding insulating layer, upper channel patterns on the upper bonding insulating layer, an upper source/drain pattern positioned on the upper bonding insulating layer and on opposite sides of the upper channel patterns, an upper gate electrode surrounding the upper channel patterns, and an upper contact structure between the upper bonding insulating layer and the upper source/drain pattern. The connection structure electrically connects the lower contact structure and the upper contact structure by penetrating the lower bonding insulating layer and the upper bonding insulating layer.

### CROSS-REFERENCE TO RELATED APPLICATION

This application claims priority to and the benefit of Korean Patent Application No. 10-2025-0004740 filed with the Korean Intellectual Property Office on January 13, 2025, the entire contents of which are incorporated herein by reference.

### BACKGROUND

### 1. Field

The present disclosure relates to a semiconductor device.

### 2. Description of the Related Art

A semiconductor is a material that belongs to a middle area between a conductor and an insulator, and refers to a material that conducts electricity under predetermined conditions. Various semiconductor devices can be manufactured, such as memory devices using the semiconductor material. The semiconductor device can be used in various electronic devices.

As the electron industry develops rapidly, the demands on the characteristics of semiconductor devices are increasing. For example, there is an increasing demand for higher reliability, higher speed and/or multi-functionality in semiconductor devices. To meet such a demanding characteristic, structures within semiconductor devices are becoming increasingly complex and integrated. As the size of the transistor decreases, coupling occurs between elements, which may decrease the operation speed of the semiconductor device and deteriorate the reliability of the semiconductor device.

### SUMMARY

According to embodiments, the reliability of semiconductor devices may be improved.

According to an embodiment, a semiconductor device comprising: a first transistor structure, a second transistor structure, and a connection structure, the first transistor structure includes: lower channel patterns, a lower source/drain pattern positioned on opposite sides of the lower channel patterns, a lower gate electrode surrounding the lower channel patterns, a lower bonding insulating layer positioned on the lower source/drain pattern and the lower gate electrode, and a lower contact structure positioned between the lower bonding insulating layer and the lower source/drain pattern, the second transistor structure includes: an upper bonding insulating layer positioned on the lower bonding insulating layer, upper channel patterns positioned on the upper bonding insulating layer, an upper source/drain pattern positioned on the upper bonding insulating layer and positioned on opposite sides of the upper channel patterns; an upper gate electrode surrounding the upper channel patterns, and an upper contact structure positioned between the upper bonding insulating layer and the upper source/drain pattern, wherein the connection structure is electrically connects the lower contact structure and the upper contact structure by penetrating the lower bonding insulating layer and the upper bonding insulating layer.

According to an embodiment, a semiconductor device comprising: a first transistor structure, a second transistor structure, and a connection structure, the first transistor structure includes: lower channel patterns, a lower source/drain pattern positioned on opposite sides of the lower channel patterns, a lower gate electrode surrounding the lower channel patterns, a lower interlayer insulating layer positioned on the lower source/drain pattern, a lower bonding insulating layer positioned on the lower interlayer insulating layer and the lower gate electrode, and a lower contact structure penetrating the lower interlayer insulating layer, connected to the lower source/drain pattern, and extending in the first direction, the second transistor structure includes: an upper bonding insulating layer positioned on the lower bonding insulating layer, upper channel patterns positioned on the upper bonding insulating layer, an upper interlayer insulating layer positioned on the upper bonding insulating layer, an upper source/drain pattern positioned on the upper interlayer insulating layer and positioned on opposite sides of the upper channel patterns, an upper gate electrode surrounding the upper channel patterns, and an upper contact structure penetrating the upper interlayer insulating layer, connected to the upper source/drain pattern, and extending in the first direction, wherein the connection structure extends in a second direction intersecting with the first direction, electrically connects the lower contact structure and the upper contact structure, and overlaps the lower contact structure in the first direction and overlaps the upper contact structure in the second direction.

According to an embodiment, a semiconductor device comprising: a first transistor structure, a second transistor structure, and a connection structure, the first transistor structure includes: lower channel patterns, a lower source/drain pattern positioned on opposite sides of the lower channel patterns, a lower gate electrode surrounding the lower channel patterns, a lower interlayer insulating layer positioned on the lower source/drain pattern, a lower bonding insulating layer positioned on the lower interlayer insulating layer and the lower gate electrode, and a lower contact structure penetrating the lower interlayer insulating layer and connected to the lower source/drain pattern, the second transistor structure includes: an upper bonding insulating layer positioned on the lower bonding insulating layer, upper channel patterns positioned on the upper bonding insulating layer, an upper interlayer insulating layer positioned on the upper bonding insulating layer, an upper source/drain pattern positioned on the upper interlayer insulating layer and positioned on opposite sides of the upper channel patterns; an upper gate electrode surrounding the upper channel patterns, and an upper contact structure penetrating the upper interlayer insulating layer and connected to the upper source/drain pattern, wherein the connection structure electrically connects the lower contact structure and the upper contact structure, and a length of the connection structure is less than or equal to the distance between the lower surface of the lower source/drain pattern and the upper surface of the upper source/drain pattern.

According to an embodiment, a method of manufacturing a semiconductor device, the method comprising: forming a second transistor structure including: upper channel patterns, an upper source/drain pattern positioned on opposite sides of the upper channel patterns, an upper gate electrode surrounding the upper channel patterns, an upper bonding insulating layer positioned on the upper source/drain pattern and the upper gate electrode, and an upper contact structure positioned between the upper bonding insulating layer and the upper source/drain pattern; forming a first transistor structure on the upper bonding insulating layer, the first transistor structure including: a lower bonding insulating layer positioned on the upper bonding insulating layer, lower channel patterns positioned on the lower bonding insulating layer, a lower source/drain pattern positioned on opposite sides of the lower channel patterns and on the lower bonding insulating layer, a lower gate electrode surrounding the lower channel patterns, and a lower contact structure positioned between the lower bonding insulating layer and the lower source/drain pattern; forming a connection recess penetrating the lower contact structure, the lower bonding insulating layer, and the upper bonding insulating layer, to expose the upper contact structure; forming a connection structure material layer in the connection recess; removing at least a portion of the connection structure material layer to form a connection structure; and flipping the first transistor structure and the second transistor structure.

Wherein the connection recess does not overlap the upper source/drain pattern.

Wherein the connection recess exposes a side surface of the lower contact structure.

Wherein forming the connection structure material layer comprises: forming a second connection electrode material layer on an inner wall and a bottom surface of the connection recess, and forming a first connection electrode material layer on the second connection electrode material layer.

Wherein the second connection electrode material layer is positioned between the lower contact structure and the first connection electrode material layer and between the upper contact structure and the first connection electrode material layer.

Wherein forming the connection recess comprises removing at least a portion of the upper contact structure.

Wherein the connection structure overlaps the lower contact structure in a first direction and overlaps the upper contact structure in a second direction intersecting the first direction.

Wherein the lower contact structure and the upper contact structure extend in the first direction, and a length of the lower contact structure in the first direction is different from a length of the upper contact structure in the first direction.

Wherein a length of the connection structure in a third direction is less than or equal to a distance between a lower surface of the lower source/drain pattern and an upper surface of the upper source/drain pattern.

Wherein a length of the connection structure in a third direction is greater than or equal to a distance between the lower contact structure and the upper contact structure.

Wherein the method improves reliability of the semiconductor device.

According to embodiments, the reliability of semiconductor devices may be improved.

### BRIEF DESCRIPTION OF THE DRAWINGS

FIG. 1 is a plan view showing a semiconductor device according to an embodiment.

FIG. 2 is a cross-sectional view taken along line A-A' of FIG. 1.

FIG. 3 is a cross-sectional view taken along line B-B' of FIG. 1.

FIG. 4 is a cross-sectional view taken along line C-C' of FIG. 1.

FIG. 5 is a circuit diagram showing an application example of a semiconductor device according to an embodiment.

FIGS. 6, 7, 8, 9, 10, and 11 are cross-sectional views corresponding to B-B' of FIG. 1, illustrating semiconductor devices according to some embodiments.

FIG. 12 is a cross-sectional view corresponding to A-A' of FIG. 1, illustrating a semiconductor device according to some embodiments.

FIG. 13 is a cross-sectional view corresponding to A-A' of FIG. 1, showing an intermediate step of a method for manufacturing a semiconductor device according to an embodiment.

FIG. 14 is a cross-sectional view corresponding to B-B' of FIG. 1, showing an intermediate step of a method for manufacturing a semiconductor device according to an embodiment.

FIG. 15 is a cross-sectional view corresponding to A-A' of FIG. 1, showing an intermediate step of a method for manufacturing a semiconductor device according to an embodiment.

FIGS. 16, 17, 18, 19, and 20 are cross-sectional views corresponding to B-B' of FIG. 1, showing intermediate steps of a method for manufacturing a semiconductor device according to an embodiment.

FIG. 21 is a cross-sectional view corresponding to A-A' of FIG. 1, showing an intermediate step of a method for manufacturing a semiconductor device according to an embodiment.

FIG. 22 is a cross-sectional view corresponding to B-B' of FIG. 1, showing an intermediate step of a method for manufacturing a semiconductor device according to an embodiment.

### DETAILED DESCRIPTION

Hereinafter, various embodiments will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and the thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is "over" or "on" another part, this includes not only cases where it is "directly over" the other part, but also cases where there are other parts in between. Conversely, when we say that a part is "directly above" another part, we mean that there is no other part in between. Also, being "above" or "on" a reference part means being located above or below the reference part, and does not necessarily mean being located "above" or "on" the opposite direction of gravity.

Additionally, throughout the specification, whenever a part is said to "include" a component, this does not mean that it excludes other components, but rather that it may include other components, unless otherwise specifically stated.

Additionally, throughout the specification, when we say "in plan", we mean when the target portion is viewed from above, and when we say "in cross section", we mean when the target portion is viewed from the side in a cross-section cut vertically.

In the drawing regarding a semiconductor device according to an embodiment, for example, the device may be formed of a GAA (Gate All Around) structure, a 3DSFET (3D Stack Field Effect Transistor) structure, etc., in which four sides of the channel are surrounded by gate electrodes. However, it is not limited to this, and the transistor may be formed with a FinFET (Fin Field Effect Transistor) structure, an MBCFETTM (Multi Bridge Channel Field Effect Transistor) structure, a CFET (Complementary Field Effect Transistor) structure, etc.

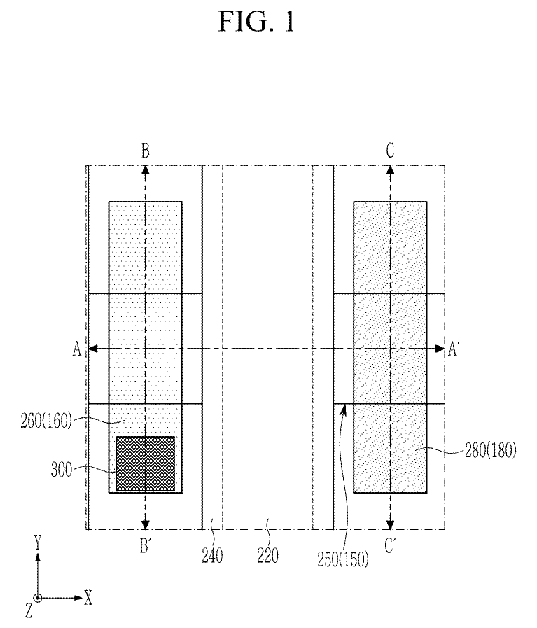

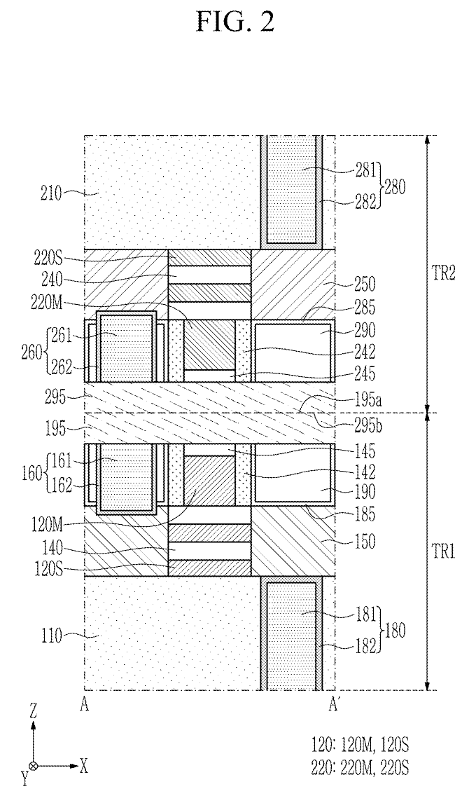

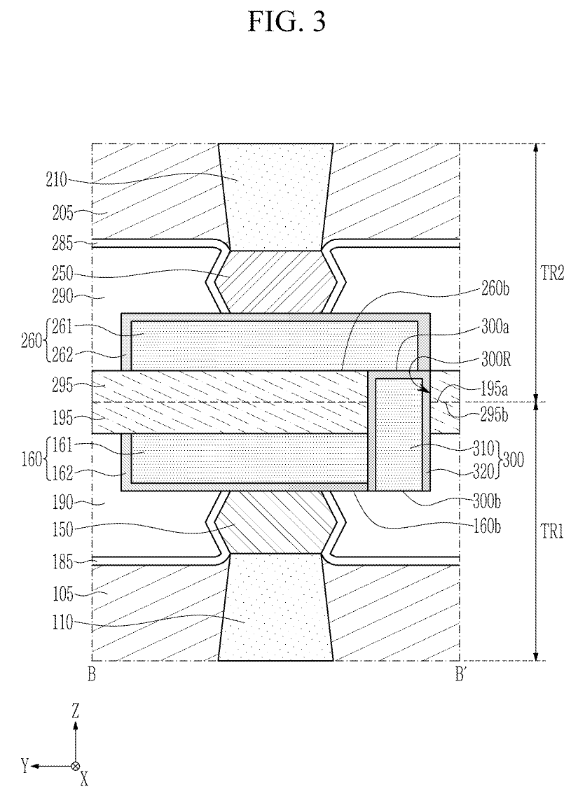

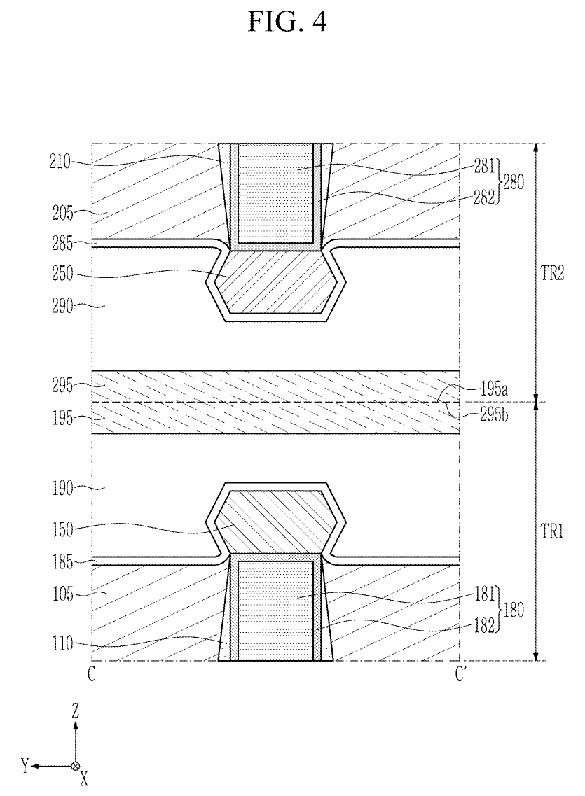

FIG. 1 is a plan view showing a semiconductor device according to an embodiment. FIG. 2 is a cross-sectional view taken along line A-A' of FIG. 1. FIG. 3 is a cross-sectional view taken along line B-B' of FIG. 1. FIG. 4 is a cross-sectional view taken along line C-C' of FIG. 1.

Referring to FIGS. 1 to 4, a semiconductor device according to an embodiment may include a first transistor structure TR1, a second transistor structure TR2 positioned on the first transistor structure TR1, and a connection structure 300 connecting the first transistor structure TR1 and the second transistor structure TR2.

The first transistor structure TR1 and the second transistor structure TR2 may each function as a transistor. For example, each of the first transistor structure TR1 and the second transistor structure TR2 may be formed of a GAA (Gate All Around) structure, an MBCFETTM (Multi Bridge Channel Field Effect Transistor) structure, etc., in which four sides of the channel are surrounded by gate electrodes. However, it is not limited thereto, and each of the first transistor structure TR1 and the second transistor structure TR2 may be formed of a FinFET (Fin Field Effect Transistor) structure, a 3DSFET (3D Stack Field Effect Transistor) structure, etc. The first transistor structure TR1 and the second transistor structure TR2 may have different conductivity types. For example, the first transistor structure TR1 may be a first-conductivity type MOSFET, and the second transistor structure TR2 may be a second-conductivity type MOSFET. Here, the first conductivity type may be N-type and the second conductivity type may be P-type, but example embodiments are not limited thereto.

The first transistor structure TR1 and the second transistor structure TR2 may be bonded to each other. Each of the first transistor structure TR1 and the second transistor structure TR2 may be separately formed and bonded to each other. For example, the first transistor structure TR1 and the second transistor structure may be formed into a 3D-SFET (three dimensional – stacked FET) structure stacked in the third direction (Z direction). The first transistor structure TR1 and the second transistor structure TR2 may have shapes that are symmetrical with respect to a reference axis extending in the first direction (X direction), but are not limited thereto. According to an embodiment, a semiconductor device may design a relatively diverse transistor structure and reduce process difficulty by connecting a separately formed first transistor structure TR1 and a second transistor structure TR2 to each other.

The first transistor structure TR1 and the second transistor structure TR2 may be electrically connected to each other. For example, the connection structure 300 may connect a first transistor structure TR1 and a second transistor structure TR2. The first transistor structure TR1 and the second transistor structure TR2 may be electrically connected to each other by the connection structure 300. In an embodiment, a first transistor structure TR1 and a second transistor structure TR2 are electrically connected to each other to perform functions such as a CMOS (Complementary MOSFET), an inverter, etc. A detailed description of this will be provided later in the description of the connection structure 300.

Hereinafter, the first transistor structure TR1 will be described.

A first transistor structure TR1 of a semiconductor device according to an embodiment may include lower channel patterns 140, a lower source/drain pattern 150 positioned on opposite sides of the lower channel patterns 140, a lower gate electrode 120 surrounding the lower channel patterns 140, a lower bonding insulating layer 195 positioned on the lower source/drain pattern 150 and the lower gate electrode 120, and a lower contact structure 160 positioned between the lower bonding insulating layer 195 and the lower source/drain pattern 150.

A first transistor structure TR1 of a semiconductor device according to an embodiment may further include a lower pattern 110.

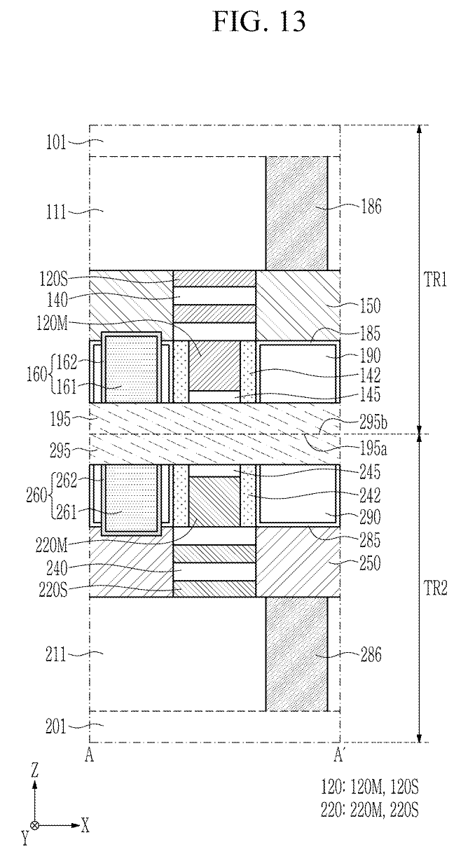

The lower pattern 110 may be formed as part of an insulating substrate. The lower pattern 110 may extend in the first direction (X direction). The lower pattern 110 may include various insulating materials. The lower pattern 110 may include an oxide, a nitride, a nitride oxide, or a combination thereof. For example, the lower pattern 110 may include silicon oxide (SiO₂). The lower pattern 110 may be a pattern formed by removing the lower active pattern (see 111 of FIG. 13) to be described later and filling the removed space with an insulating material.

A semiconductor device according to an embodiment may further include a first base insulating layer.

The first base insulating layer may be an insulating substrate. The first base insulating layer may comprise various insulating materials. The first base insulating layer may include an oxide, a nitride, a nitride oxide or a combination thereof. For example, the first base insulating layer may include silicon oxide (SiO₂). In an embodiment, the lower pattern 110 may be formed as part of the first base insulating layer. In an embodiment, a first transistor structure TR1 may be provided on a first base insulating layer, but example embodiments are not limited thereto. The upper surface and the lower surface of the first base insulating layer may be formed as planes parallel to the first direction (X direction) and a second direction (Y direction) intersecting the first direction (X direction). Here, the second direction (Y direction) may be a direction intersecting with the first direction (X direction). In an embodiment, the second direction (Y direction) may be a direction orthogonal to the first direction (X direction).

The lower channel patterns 140 may be positioned on the lower pattern 110. The lower channel patterns 140 may be spaced apart from the lower pattern 110 in a third direction (Z direction). Each of the lower channel patterns 140 may be spaced apart in a third direction (Z direction). Here, the third direction (Z direction) may be a direction intersecting the first direction (X direction) and the second direction (Y direction). In an embodiment, the widths of the lower channel patterns 140 along the first direction (X direction) may be substantially the same, but are not limited thereto. As another example, the widths of the lower channel patterns 140 along the first direction (X direction) may be different.

The lower channel patterns 140 may include a semiconductor material. For example, the lower channel patterns 140 may include an elemental semiconductor material such as silicon (Si) or germanium (Ge). The lower channel patterns 140 may be formed by etching a portion of the first substrate (see 101 of FIG. 13) or may include an epitaxial layer grown from the first substrate (see 101 of FIG. 13).

The lower channel patterns 140 may include a compound semiconductor, for example, a group IV-IV compound semiconductor or a group III-V compound semiconductor. Here, the IV-IV group compound semiconductor may be, for example, a binary compound or ternary compound containing at least two or more of carbon (C), silicon (Si), germanium (Ge), and tin (Sn). The III-V group compound semiconductor may be, for example, a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements. In an embodiment, the lower channel patterns 140 may include silicon (Si). As another example, the lower channel patterns 140 may include silicon germanium (SiGe).

In FIG. 2, two lower channel patterns 140 are illustrated as being stacked and spaced apart in the third direction (Z direction), but is not limited thereto. The number of lower channel patterns 140 may be varied.

As illustrated in FIGS. 3 and 4, the first transistor structure TR1 of the semiconductor device according to an embodiment may further include a lower field insulating layer 105 positioned on opposite sides of the lower pattern 110.

The lower field insulating layer 105 may cover at least a portion of the side surface of the lower pattern 110. For example, as shown in FIGS. 3 and 4, the lower field insulating layer 105 may cover opposite sides of the lower pattern 110. The lower field insulating layer 105 may overlap the lower pattern 110 in the second direction (Y direction). Additionally, the lower field insulating layer 105 may not be positioned on the upper surface of the lower pattern 110. The lower field insulating layer 105 may include, for example, an oxide, a nitride, a nitride oxide, or a combination thereof. The lower field insulating layer 105 is illustrated as a single film, but this is only for convenience of explanation and is not limited thereto.

The lower source/drain pattern 150 may be positioned on the lower pattern 110. The lower source/drain pattern 150 may be positioned on at least one side of the lower channel patterns 140. For example, the lower source/drain pattern 150 may be positioned on opposite sides of the lower channel patterns 140 along the first direction (X direction). The lower source/drain pattern 150 may be in contact with the side surface of the lower channel patterns 140 and the upper surface of the lower pattern 110. The lower source/drain pattern 150 may be electrically connected to the lower channel patterns 140. The upper surface of the lower source/drain pattern 150 may be positioned at substantially the same level as the upper surfaces of the lower channel patterns 140, but example embodiments are not limited thereto.

The lower source/drain pattern 150 may be epitaxial patterns formed by a selective epitaxial growth process using the lower channel patterns 140 and the lower active pattern (see 111 in FIG. 13) as seeds. The lower source/drain pattern 150 may include a semiconductor material. For example, the lower source/drain pattern 150 may include silicon (Si) or silicon germanium (SiGe). The lower source/drain pattern 150 may have a first conductivity type. The lower source/drain pattern 150 may be doped with a first conductivity type impurity. Here, the first conductivity type may be N-type, but example embodiments are not limited thereto. For example, the lower source/drain pattern 150 may include P, Sb, As, or a combination thereof.

In FIGS. 2 to 4, the lower source/drain pattern 150 is described as being formed as a single layer, but example embodiments are not limited thereto. As another example, the lower source/drain pattern 150 may be formed of a double layer including a semiconductor material, or may be formed of three or more layers.

The lower gate electrode 120 may be positioned on the lower pattern 110. The lower gate electrode 120 may extend in the second direction (Y direction). The lower gate electrode 120 may cross the lower pattern 110 on a plane. The lower gate electrode 120 may intersect the lower pattern 110 on a plane. For example, the lower gate electrode 120 may extend in the second direction (Y direction).

The lower gate electrode 120 may surround the lower channel patterns 140. For example, the lower gate electrode 120 may cover the side surface, the lower surface, and the upper surface of each of the lower channel patterns 140 along the second direction (Y direction). That is, the lower gate electrode 120 may completely surround the four sides of each of the lower channel patterns 140. Accordingly, the side surface, the lower surface, and the upper surface of the lower channel patterns 140 may each come into contact with the lower gate electrode 120. A lower source/drain pattern 150 may be positioned on opposite sides of the lower gate electrode 120. Semiconductor device includes a plurality of lower source/drain patterns 150 and the lower gate electrode 120 may be positioned between adjacent the lower source/drain patterns 150 in the first direction (X direction).

The lower gate electrode 120 of the semiconductor device according to an embodiment may include a plurality of lower sub-gate electrodes 120S and a lower main gate electrode 120M. A plurality of lower sub-gate electrodes 120S may be positioned between adjacent lower channel patterns 140 in the third direction (Z direction) and between the lower pattern 110 and the lowermost lower channel pattern. A plurality of lower sub-gate electrodes 120S may be adjacent to the lower source/drain pattern 150. The lower main gate electrode 120M may be positioned on the lower channel pattern positioned at the top.

According to an embodiment, the number of the plurality of lower sub-gate electrodes 120S may be proportional to the number of lower channel patterns 140 stacked in the third direction (Z direction). For example, the number of the plurality of lower sub-gate electrodes 120S may be equal to the number of lower channel patterns 140 stacked in the third direction (Z direction). For example, as illustrated in FIG. 2, the number of multiple lower sub-gate electrodes 120S may be two. However, it is not limited thereto, and the first transistor structure TR1 may include three or more lower sub-gate electrodes 120S.

The lower gate electrode 120 may include at least one of a metal, a metal alloy, a conductive metal nitride, a metal silicide, a doped semiconductor material, a conductive metal oxide, and a conductive metal oxynitride. The lower gate electrode 120 may be, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), It may include at least one of, but example embodiments are not limited thereto, molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal nitrides may include, but are not limited to, oxidized forms of the materials described above.

A first transistor structure TR1 of a semiconductor device according to an embodiment may further include a lower gate insulating layer surrounding a lower gate electrode 120.

The lower gate insulating layer may surround the lower sub-gate electrode 120S. The lower gate insulating layer may be positioned between the lower sub-gate electrode 120S and the lower source/drain pattern 150 and between the lower sub-gate electrode 120S and the lower channel patterns 140. Additionally, the lower gate insulating layer may be positioned between the lower main gate electrode 120M and the lower channel pattern positioned at the top. The lower gate insulating layer may include various insulating materials. The lower gate insulating layer may be composed of a single layer or multiple layers. In this case, at least some layers of the lower gate insulating layer may include a high-k material. Here, the high-k material may be a material having a higher dielectric constant than silicon oxide (SiO₂), such as hafnium oxide (HfO), aluminum oxide (AlO), or tantalum oxide (TaO).

A semiconductor device according to an embodiment may further include a first gate spacer 142. The first gate spacer 142 may be positioned on the side of the lower gate electrode 120. For example, the first gate spacer 142 may be positioned between the lower main gate electrode 120M and the lower interlayer insulating layer 190 to be described later. The first gate spacer 142 may not be positioned on the side surface of the plurality of lower sub-gate electrodes 120S.

The first gate spacer 142 may include various insulating materials. For example, the first gate spacer 142 may include silicon nitride (SiN). However, it is not limited thereto, and the first gate spacer 142 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. In FIG. 2, the first gate spacer 142 is illustrated as being formed of a single layer, but example embodiments are not limited thereto. For example, the first gate spacer 142 may be formed of multiple layers.

A semiconductor device according to an embodiment may further include a first capping layer 145 positioned on the lower gate electrode 120.

The first capping layer 145 may be positioned on the lower gate electrode 120. The first capping layer 145 may be positioned on the side surface of the first gate spacer 142, but example embodiments are not limited thereto. In an embodiment, the first capping layer 145 may be positioned on the first gate spacer 142 and the lower gate electrode 120. The first capping layer 145 may include, for example, at least one of silicon nitride (SiN), silicon oxynitride (SiON), silicon carbon nitride (SiCN), silicon oxycarbonitride (SiOCN), and combinations thereof. The first capping layer 145 may include a material having an etching selectivity with respect to the lower interlayer insulating layer 190 to be described later.

A first transistor structure TR1 of a semiconductor device according to an embodiment may further include a lower interlayer insulating layer 190 positioned on a lower source/drain pattern 150. The lower interlayer insulating layer 190 may not cover the upper surface of the lower gate electrode 120. The lower interlayer insulating layer 190 may be positioned on the side surface of the lower gate electrode 120. The lower interlayer insulating layer 190 may be positioned on the side surface of the first gate spacer 142. As illustrated in FIGS. 3 and 4, the lower interlayer insulating layer 190 may surround at least a portion of the lower source/drain pattern 150.

The lower interlayer insulating layer 190 may include, for example, at least one of silicon oxide (SiO₂), silicon nitride (SiN), silicon oxynitride (SiON), and a low-k material. Low-k materials include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), and TriMethylSilyl Borate. (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate) Glass), SiLK, Amorphous Fluorinated Carbon, silica aerogels, silica xerogels, may include, but example embodiments are not limited thereto, mesoporous silica or combinations thereof.

A first transistor structure TR1 of a semiconductor device according to an embodiment may further include a first etch stop layer 185 positioned between the lower interlayer insulating layer 190 and the lower source/drain pattern 150 and between the lower interlayer insulating layer 190 and the first gate spacer 142.

As illustrated in FIG. 2, the first etch stop layer 185 may be positioned on the side surface of the first gate spacer 142 and on the upper surface of the lower source/drain pattern 150. Additionally, as illustrated in FIGS. 3 and 4, the first etch stop layer 185 may surround at least a portion of the lower source/drain pattern 150. The first etch stop layer 185 may be positioned on the lower field insulating layer 105. The first etch stop layer 185 may be positioned between the lower field insulating layer 105 and the lower interlayer insulating layer 190. The first etch stop layer 185 may include a material having an etching selectivity with respect to the lower interlayer insulating layer 190. Additionally, the first etch stop layer 185 may include a material having an etching selectivity with respect to the lower source/drain pattern 150. The first etch stop layer 185 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The lower bonding insulating layer 195 may be positioned on the lower source/drain pattern 150 and the lower gate electrode 120. The lower bonding insulating layer 195 may be positioned on the lower interlayer insulating layer 190. Additionally, the lower bonding insulating layer 195 may be positioned on the first gate spacer 142 and the first capping layer 145. The lower bonding insulating layer 195 may be in contact with the upper surface of the lower interlayer insulating layer 190, the upper surface of the first gate spacer 142, and the upper surface of the first capping layer 145, but example embodiments are not limited thereto.

The lower bonding insulating layer 195 may include a first surface 195a facing the second transistor structure TR2 and a second surface opposite to the first surface 195a. The first surface 195a of the lower bonding insulating layer 195 may form a junction interface with the upper bonding insulating layer 295 of the second transistor structure TR2. The lower bonding insulating layer 195 may be bonded to the upper bonding insulating layer 295 of the second transistor structure TR2.

The lower bonding insulating layer 195 may include various insulating materials. For example, the lower bonding insulating layer 195 may include silicon oxide (SiO₂). However, and not limited thereto, as another example, the lower bonding insulating layer 195 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The lower contact structure 160 may be positioned between the lower bonding insulating layer 195 and the lower source/drain pattern 150. The lower contact structure 160 may be positioned on the lower source/drain pattern 150. The lower contact structure 160 may be connected to the lower source/drain pattern 150 by penetrating the lower interlayer insulating layer 190. At least a portion of the lower contact structure 160 may be positioned within the lower source/drain pattern 150. At least a portion of the lower contact structure 160 may be surrounded by the lower source/drain pattern 150, but example embodiments are not limited thereto. At least a portion of the lower contact structure 160 may overlap the lower channel patterns 140 in the first direction (X direction). The lower contact structure 160 may be electrically connected to the lower source/drain pattern 150. The lower contact structure 160 may be positioned between the lower source/drain pattern 150 and the upper source/drain pattern 250 to be described later.

As illustrated in FIG. 3, the lower contact structure 160 may extend in the second direction (Y direction). The lower contact structure 160 may extend parallel to the lower gate electrode 120. The lower contact structure 160 may overlap the lower source/drain pattern 150 in the third direction (Z direction). A length of the lower contact structure 160 along the second direction (Y direction) may be greater than a length of the lower source/drain pattern 150 along the second direction (Y direction).

The lower contact structure 160 may include a first surface facing the lower bonding insulating layer 195 and a second surface 160b opposite the first surface. The first surface of the lower contact structure 160 may be a surface facing the upper source/drain pattern 250 of the second transistor structure TR2, and the second surface 160b of the lower contact structure 160 may be a surface facing the lower source/drain pattern 150. The first surface of the lower contact structure 160 may correspond to the upper surface of the lower contact structure 160, and the second surface 160b of the lower contact structure 160 may correspond to the lower surface of the lower contact structure 160, but example embodiments are not limited thereto.

The second surface 160b of the lower contact structure 160 may be in contact with the lower source/drain pattern 150. Additionally, at least a portion of the second surface 160b of the lower contact structure 160 may be in contact with the lower interlayer insulating layer 190. The first surface of the lower contact structure 160 may be in contact with the lower bonding insulating layer 195.

The lower contact structure 160 may include a first lower contact electrode 161 and a second lower contact electrode 162 surrounding the first lower contact electrode 161. The first lower contact electrode 161 may be positioned between the lower interlayer insulating layer 190 and the lower bonding insulating layer 195. The upper surface of the first lower contact electrode 161 may be in contact with the lower bonding insulating layer 195. The second lower contact electrode 162 may cover the lower surface and side surface of the first lower contact electrode 161. The second lower contact electrode 162 may not be positioned on the upper surface of the first lower contact electrode 161.

The first lower contact electrode 161 and the second lower contact electrode 162 may include a conductive material. The first lower contact electrode 161 and the second lower contact electrode 162 may include, for example, at least one of a metal, a metal alloy, a conductive metal nitride, a conductive metal carbide, a conductive metal oxide, a conductive metal carbonitride, and a two-dimensional (2D) material. For example, the first lower contact electrode 161 may include tungsten (W), molybdenum (Mo), or a combination thereof, and the second lower contact electrode 162 may include titanium nitride (TiN). As another example, the second lower contact electrode 162 may include at least one metal silicide film.

A first transistor structure TR1 of a semiconductor device according to an embodiment may further include a lower penetrating structure 180 penetrating the lower pattern 110.

The lower penetrating structure 180 may be positioned on the lower surface of the lower source/drain pattern 150. The lower penetrating structure 180 may penetrate the lower pattern 110 and be connected to the lower source/drain pattern 150. The lower penetrating structure 180 may extend in the second direction (Y direction). The lower penetrating structure 180 may extend parallel to the lower contact structure 160. The lower penetrating structure 180 may overlap the lower source/drain pattern 150 in the third direction (Z direction). A length of the lower penetrating structure 180 along the second direction (Y direction) may be greater than a length of the lower source/drain pattern 150 along the second direction (Y direction).

The lower penetrating structure 180 may include a first lower through-via 181 and a second lower through-via 182 surrounding the first lower through-via 181. The second lower through-via 182 may cover the upper surface and side surface of the first lower through-via 181.

The first lower through-via 181 and the second lower through-via 182 may include a conductive material. The first lower through-via 181 and the second lower through-via 182 may include the same material as the first lower contact electrode 161 and the second lower contact electrode 162. The first lower through-via 181 and the second lower through-via 182 may include at least one of, for example, a metal, a metal alloy, a conductive metal nitride, a conductive metal carbide, a conductive metal oxide, a conductive metal carbonitride, and a two-dimensional (2D) material.

Hereinafter, the second transistor structure TR2 positioned on the first transistor structure TR1 will be described.

A second transistor structure TR2 of a semiconductor device according to an embodiment may include an upper bonding insulating layer 295 positioned on a lower bonding insulating layer 195, upper channel patterns 240 positioned on the upper bonding insulating layer 295, an upper source/drain pattern 250 positioned on the upper bonding insulating layer 295, an upper gate electrode 220 surrounding the upper channel patterns 240, and an upper contact structure 260 positioned between the upper bonding insulating layer 295 and the upper source/drain pattern 250.

The upper bonding insulating layer 295 may be positioned on the lower bonding insulating layer 195. The upper bonding insulating layer 295 may include a second surface 295b facing the first transistor structure TR1 and a first surface opposite to the second surface 295b. The second surface 295b of the upper bonding insulating layer 295 may form a bonding interface with the first surface 195a of the lower bonding insulating layer 195. That is, the second surface 295b of the upper bonding insulating layer 295 may come into contact with the first surface 195a of the lower bonding insulating layer 195.

The upper bonding insulating layer 295 may include various insulating materials. The upper bonding insulating layer 295 may include the same material as the lower bonding insulating layer 195. For example, the upper bonding insulating layer 295 may include silicon oxide (SiO₂). However, and not limited thereto, as another example, the upper bonding insulating layer 295 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The upper channel patterns 240 may be positioned on the upper bonding insulating layer 295. The upper channel patterns 240 may be spaced apart from the lower channel patterns 140 in a third direction (Z direction). Each of the upper channel patterns 240 may be spaced apart in a third direction (Z direction). In an embodiment, the widths of the upper channel patterns 240 along the first direction (X direction) may be substantially the same, but are not limited thereto. As another example, the widths of the upper channel patterns 240 along the first direction (X direction) may be different.

The upper channel patterns 240 may include a semiconductor material. The upper channel patterns 240 may include, but are not limited to, the same material as the lower channel patterns 140. For example, the upper channel patterns 240 may include an elemental semiconductor material such as silicon (Si) or germanium (Ge). The upper channel patterns 240 may be formed by etching a portion of the second substrate (see 201 of FIG. 13) or may include an epitaxial layer grown from the second substrate (see 201 of FIG. 13).

The upper channel patterns 240 may include a compound semiconductor, for example, a group IV-IV compound semiconductor or a group III-V compound semiconductor. Here, the IV-IV group compound semiconductor may be, for example, a binary compound or ternary compound containing at least two or more of carbon (C), silicon (Si), germanium (Ge), and tin (Sn). The III-V group compound semiconductor may be, for example, a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements. In an embodiment, the upper channel patterns 240 may include silicon (Si). As another example, the upper channel patterns 240 may include silicon germanium (SiGe).

In FIG. 2, two upper channel patterns 240 are illustrated as being stacked and spaced apart in the third direction (Z direction), but the present disclosure is not limited thereto. The number of upper channel patterns 240 may be varied.

The upper source/drain pattern 250 may be positioned on the upper bonding insulating layer 295. The upper source/drain pattern 250 may be positioned on at least one side of the upper channel patterns 240. For example, the upper source/drain pattern 250 may be positioned on opposite sides of the upper channel patterns 240 along the first direction (X direction). The upper source/drain pattern 250 may be in contact with the side surface of the upper channel patterns 240. The upper source/drain pattern 250 may be electrically connected to the upper channel patterns 240. The upper surface of the upper source/drain pattern 250 may be positioned at substantially the same level as the upper surfaces of the upper channel patterns 240, but example embodiments are not limited thereto.

The upper source/drain pattern 250 may be positioned spaced apart from the lower source/drain pattern 150 in the third direction (Z direction). The upper source/drain pattern 250 may overlap the lower source/drain pattern 150 in the third direction (Z direction). A side of the upper source/drain pattern 250 may be aligned with the side surface of the lower source/drain pattern 150, but example embodiments are not limited thereto.

The upper source/drain pattern 250 may be epitaxial patterns formed by a selective epitaxial growth process using the upper channel patterns 240 and the upper active pattern (see 211 in FIG. 13) as seeds. The upper source/drain pattern 250 may include a semiconductor material. The upper source/drain pattern 250 may include the same material as the lower source/drain pattern 150. For example, the upper source/drain pattern 250 may include silicon (Si) or silicon germanium (SiGe). The upper source/drain pattern 250 may have a second conductivity type different from the first conductivity type. The upper source/drain pattern 250 may be doped with a second conductivity type impurity. Here, the second conductivity type may be P type, but example embodiments are not limited thereto. For example, the upper source/drain pattern 250 may include B, V, In, Ga, Al, or a combination thereof.

In FIGS. 2 to 4, the upper source/drain pattern 250 is described as being formed as a single layer, but example embodiments are not limited thereto. As another example, the upper source/drain pattern 250 may be formed of a double layer including a semiconductor material, or may be formed of three or more layers.

The upper gate electrode 220 may be positioned on the upper bonding insulating layer 295. The upper gate electrode 220 may extend in the second direction (Y direction). The upper gate electrode 220 may surround the upper channel patterns 240. For example, the upper gate electrode 220 may cover the side surface, and upper surface along the second direction (Y direction) of each of the upper channel patterns 240. That is, the upper gate electrode 220 may completely surround the four sides of each of the upper channel patterns 240. Accordingly, the side surface, and upper surface of the upper channel patterns 240 may each come into contact with the upper gate electrode 220. The upper source/drain pattern 250 may be positioned on opposite sides of the upper gate electrode 220. That is, the upper gate electrode 220 may be positioned between adjacent the upper source/drain pattern 250 in the first direction (X direction).

The upper gate electrode 220 of the semiconductor device according to an embodiment may include a plurality of upper sub-gate electrodes 220S and an upper main gate electrode 220M. A plurality of upper sub-gate electrodes 220S may be positioned between upper channel patterns 240 adjacent in the third direction (Z direction) and between the upper pattern 210 to be described later and the upper channel pattern positioned at the top. A plurality of upper sub-gate electrodes 220S may be adjacent to the upper source/drain pattern 250. The upper main gate electrode 220M may be positioned below the upper channel pattern positioned at the lowest position.

According to an embodiment, the number of the plurality of upper sub-gate electrodes 220S may be proportional to the number of upper channel patterns 240 stacked in the third direction (Z direction). For example, as illustrated in FIG. 2, the number of multiple upper sub-gate electrodes 220S may be two. However, it is not limited thereto, and the second transistor structure TR2 may include three or more upper sub-gate electrodes 220S.

The upper gate electrode 220 may include at least one of a metal, a metal alloy, a conductive metal nitride, a metal silicide, a doped semiconductor material, a conductive metal oxide, and a conductive metal oxynitride. The upper gate electrode 220 may include the same material as the lower gate electrode 120, but example embodiments are not limited thereto.

A first transistor structure TR1 of a semiconductor device according to an embodiment may further include an upper gate insulating layer surrounding the upper gate electrode 220.

The upper gate insulating layer may surround the upper sub-gate electrodes 220S. The upper gate insulating layer may be positioned between the upper sub-gate electrodes 220S and the upper source/drain pattern 250 and between the upper sub-gate electrodes 220S and the upper channel patterns 240. Additionally, the upper gate insulating layer may be positioned between the upper main gate electrode 220M and the upper channel pattern positioned at the bottom. The upper gate insulating layer may include various insulating materials. The upper gate insulating layer may be composed of a single layer or multiple layers. In this case, at least some layers of the upper gate insulating layer may include a high-k material. Here, the high-k material may be a material having a higher dielectric constant than silicon oxide (SiO₂), such as hafnium oxide (HfO), aluminum oxide (AlO), or tantalum oxide (TaO).

A semiconductor device according to an embodiment may further include a second gate spacer 242. The second gate spacer 242 may be positioned on the side surface of the upper gate electrode 220. For example, the second gate spacer 242 may be positioned between the upper main gate electrode 220M and the upper interlayer insulating layer 290 to be described later. The second gate spacer 242 may not be positioned on the side surface of the plurality of upper sub-gate electrodes 220S.

The second gate spacer 242 may include various insulating materials. The second gate spacer 242 may include the same material as the first gate spacer 142, but example embodiments are not limited thereto. For example, the second gate spacer 242 may include silicon nitride (SiN). However, it is not limited thereto, and the second gate spacer 242 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. In FIG. 2, the second gate spacer 242 is illustrated as being formed of a single layer, but example embodiments are not limited thereto. For example, the second gate spacer 242 may be formed of multiple layers.

A semiconductor device according to an embodiment may further include a second capping layer 245 positioned between the upper gate electrode 220 and the upper bonding insulating layer 295.

The second capping layer 245 may be positioned between the upper gate electrode 220 and the upper bonding insulating layer 295. The second capping layer 245 may be positioned on the side surface of the second gate spacer 242, but example embodiments are not limited thereto. The second capping layer 245 may include the same material as the first capping layer 145, but example embodiments are not limited thereto. The second capping layer 245 may include, for example, at least one of silicon nitride (SiN), silicon oxynitride (SiON), silicon carbon nitride (SiCN), silicon oxycarbonitride (SiOCN), and combinations thereof. The second capping layer 245 may include a material having an etching selectivity with respect to the upper interlayer insulating layer 290 to be described later.

A second transistor structure TR2 of a semiconductor device according to an embodiment may further include an upper interlayer insulating layer 290 positioned between the upper source/drain pattern 250 and the upper bonding insulating layer 295.

The upper interlayer insulating layer 290 may be positioned between the upper source/drain pattern 250 and the upper bonding insulating layer 295. The upper interlayer insulating layer 290 may not cover the lower surface of the upper gate electrode 220. The upper interlayer insulating layer 290 may be positioned on the side surface of the upper gate electrode 220. The upper interlayer insulating layer 290 may be positioned on the side surface of the second gate spacer 242. As illustrated in FIGS. 3 and 4, the upper interlayer insulating layer 290 may surround at least a portion of the upper source/drain pattern 250.

The upper interlayer insulating layer 290 may include the same material as the lower interlayer insulating layer 190. The upper interlayer insulating layer 290 may include, for example, at least one of silicon oxide (SiO₂), silicon nitride (SiN), silicon oxynitride (SiON), and a low-k material.

As illustrated in FIG. 2, the second etch stop layer 285 may be positioned on the side surface of the second gate spacer 242 and on the lower surface of the upper source/drain pattern 250. Additionally, as illustrated in FIGS. 3 and 4, the second etch stop layer 285 may surround at least a portion of the upper source/drain pattern 250. The second etch stop layer 285 may be positioned on the upper field insulating layer 205 to be described later. The second etch stop layer 285 may be positioned between the upper field insulating layer 205 and the upper interlayer insulating layer 290. The second etch stop layer 285 may include the same material as the first etch stop layer 185, but example embodiments are not limited thereto.

A second transistor structure TR2 of a semiconductor device according to an embodiment may further include a second etch stop layer 285 positioned between the upper interlayer insulating layer 290 and the upper source/drain pattern 250 and between the upper interlayer insulating layer 290 and the second gate spacer 242.

The upper contact structure 260 may be positioned between the upper bonding insulating layer 295 and the upper source/drain pattern 250. The upper contact structure 260 may be connected to the upper source/drain pattern 250 by penetrating the upper interlayer insulating layer 290. At least a portion of the upper contact structure 260 may be positioned within the upper source/drain pattern 250. At least a portion of the upper contact structure 260 may be surrounded by the upper source/drain pattern 250, but example embodiments are not limited thereto. At least a portion of the upper contact structure 260 may overlap the upper channel patterns 240 in the first direction (X direction). The upper contact structure 260 may be electrically connected to the upper source/drain pattern 250. The upper contact structure 260 may be positioned between the lower source/drain pattern 150 and the upper source/drain pattern 250. The upper contact structure 260 may be positioned between the lower contact structure 160 and the upper source/drain pattern 250.

As illustrated in FIG. 3, the upper contact structure 260 may extend in the second direction (Y direction). The upper contact structure 260 may extend parallel to the upper gate electrode 220. Additionally, the upper contact structure 260 may extend parallel to the lower contact structure 160. The upper contact structure 260 may overlap the upper source/drain pattern 250 in the third direction (Z direction). A length of the upper contact structure 260 along the second direction (Y direction) may be greater than a length of the upper source/drain pattern 250 along the second direction (Y direction).

A length of the upper contact structure 260 along the second direction (Y direction) may be different from a length of the lower contact structure 160 along the second direction (Y direction). For example, a length of the upper contact structure 260 along the second direction (Y direction) may be longer than a length of the lower contact structure 160 along the second direction (Y direction). This may be due to the process characteristics of forming a connection recess 300R by removing at least a portion of the lower contact structure 160 after forming the lower contact structure 160, and forming the connection structure 300 within the connection recess 300R.

The upper contact structure 260 may include a first surface facing the upper source/drain pattern 250 and a second surface 260b opposite the first surface. The second surface 260b of the upper contact structure 260 may be a surface facing the lower source/drain pattern 150. The first surface of the upper contact structure 260 may correspond to the upper surface of the upper contact structure 260, and the second surface 260b of the upper contact structure 260 may correspond to the lower surface of the upper contact structure 260, but example embodiments are not limited thereto.

The first surface of the upper contact structure 260 may be in contact with the upper source/drain pattern 250. Additionally, at least a portion of the first surface of the upper contact structure 260 may be in contact with the upper interlayer insulating layer 290. The second surface 260b of the upper contact structure 260 may be in contact with the upper bonding insulating layer 295.

The upper contact structure 260 may include a first upper contact electrode 261 and a second upper contact electrode 262 surrounding the first upper contact electrode 261. The first upper contact electrode 261 may be positioned between the upper interlayer insulating layer 290 and the upper bonding insulating layer 295. The lower surface of the first upper contact electrode 261 may be in contact with the upper bonding insulating layer 295. The second upper contact electrode 262 may cover the upper surface and side surface of the first upper contact electrode 261. The second upper contact electrode 262 may not be positioned on the lower surface of the first upper contact electrode 261.

The first upper contact electrode 261 and the second upper contact electrode 262 may include a conductive material. The first upper contact electrode 261 and the second upper contact electrode 262 may include at least one of, for example, a metal, a metal alloy, a conductive metal nitride, a conductive metal carbide, a conductive metal oxide, a conductive metal carbonitride, and a two-dimensional (2D) material. For example, the first upper contact electrode 261 may include tungsten (W), molybdenum (Mo), or a combination thereof, and the second upper contact electrode 262 may include titanium nitride (TiN). As another example, the second upper contact electrode 262 may include at least one metal silicide film.

A second transistor structure TR2 of a semiconductor device according to an embodiment may further include an upper pattern 210 positioned on an upper source/drain pattern 250. The upper pattern 210 may be formed as part of an insulating substrate. The upper pattern 210 may extend in the first direction (X direction). The upper pattern 210 may include various insulating materials. The upper pattern 210 may include the same material as the lower pattern 110, but example embodiments are not limited thereto. The upper pattern 210 may include an oxide, a nitride, a oxynitride, or a combination thereof. For example, the upper pattern 210 may include silicon oxide (SiO₂). The upper pattern 210 may be a pattern formed by removing the upper active pattern (see 211 of FIG. 13) to be described later and filling the removed space with an insulating material.

As illustrated in FIGS. 3 and 4, the second transistor structure TR2 of the semiconductor device according to an embodiment may further include an upper field insulating layer 205 positioned on opposite sides of the upper pattern 210.

The upper field insulating layer 205 may cover at least a portion of the side surface of the upper pattern 210. For example, as shown in FIGS. 3 and 4, the upper field insulating layer 205 may cover opposite side surfaces of the upper pattern 210. The upper field insulating layer 205 may overlap the upper pattern 210 in the second direction (Y direction). Additionally, the upper field insulating layer 205 may not be positioned on the lower surface of the upper pattern 210. The upper field insulating layer 205 may include the same material as the lower field insulating layer 105, but example embodiments are not limited thereto. The upper field insulating layer 205 may include, for example, an oxide, a nitride, a nitride oxide, or a combination thereof. The upper field insulating layer 205 is illustrated as a single film, but this is only for convenience of explanation and is not limited thereto.

A second transistor structure TR2 of a semiconductor device according to an embodiment may further include an upper penetrating structure 280 penetrating the upper pattern 210.

The upper penetrating structure 280 may be positioned on the upper surface of the upper source/drain pattern 250. The upper penetrating structure 280 may penetrate the upper pattern 210 and be connected to the upper source/drain pattern 250. The upper penetrating structure 280 may extend in the second direction (Y direction). The upper penetrating structure 280 may extend parallel to the upper contact structure 260. The upper penetrating structure 280 may overlap the upper source/drain pattern 250 in the third direction (Z direction). A length of the upper penetrating structure 280 along the second direction (Y direction) may be greater than a length of the upper source/drain pattern 250 along the second direction (Y direction).

The upper penetrating structure 280 may include a first upper through-via 281 and a second upper through-via 282 surrounding the first upper through-via 281. The second upper through-via 282 may cover the upper surface and side surface of the first upper through-via 281.

The first upper through-via 281 and the second upper through-via 282 may include a conductive material. The first upper through-via 281 may include the same material as the first lower through-via 181, and the second upper through-via 282 may include the same material as the second lower through-via 182. The first upper through-via 281 and the second upper through-via 282 may include the same material as the first upper contact electrode 261 and the second upper contact electrode 262. The first upper through-via 281 and the second upper through-via 282 may include at least one of the following: a metal, a metal alloy, a conductive metal nitride, a conductive metal carbide, a conductive metal oxide, a conductive metal carbonitride, and a two-dimensional (2D) material.

As illustrated in FIG. 3, a connection structure 300 of a semiconductor device according to an embodiment may connect a first transistor structure TR1 and a second transistor structure TR2. For example, the connection structure 300 may connect the lower contact structure 160 and the upper contact structure 260. Accordingly, the lower source/drain pattern 150 connected to the lower contact structure 160 and the upper source/drain pattern 250 connected to the upper contact structure 260 may be electrically connected through the connection structure 300.

the connection structure 300 may be positioned on the lower interlayer insulating layer 190. the connection structure 300 may extend in the third direction (Z direction) through the upper bonding insulating layer 295 and the lower bonding insulating layer 195. the connection structure 300 may be positioned within a connection recess 300R that penetrates the lower bonding insulating layer 195 and the upper bonding insulating layer 295 and recesses at least a portion of the lower interlayer insulating layer 190. The inner wall of the connection recess 300R may be defined by the upper bonding insulating layer 295, the lower bonding insulating layer 195, the lower contact structure 160, and the lower interlayer insulating layer 190. For example, one side wall along the second direction (Y direction) of the connection recess 300R may be defined by the upper bonding insulating layer 295, the lower bonding insulating layer 195, and the lower contact structure 160, and the other side wall opposite to the one side wall of the connection recess 300R may be defined by the upper bonding insulating layer 295, the lower bonding insulating layer 195, the lower contact structure 160, and the lower interlayer insulating layer 190. The bottom surface of the connection recess 300R may be defined by the upper contact structure 260. the connection structure 300 may be in contact with the side surface of the lower contact structure 160 and the second surface 260b of the upper contact structure 260.

the connection structure 300 may include a first surface 300a facing the upper source/drain pattern 250 and a second surface 300b opposite to the first surface 300a. The second surface 300b of the connection structure 300 may be a surface facing the lower source/drain pattern 150. The first surface 300a of the connection structure 300 may correspond to the upper surface of the connection structure 300, and the second surface 300b of the connection structure 300 may correspond to the lower surface of the connection structure 300, but example embodiments are not limited thereto.

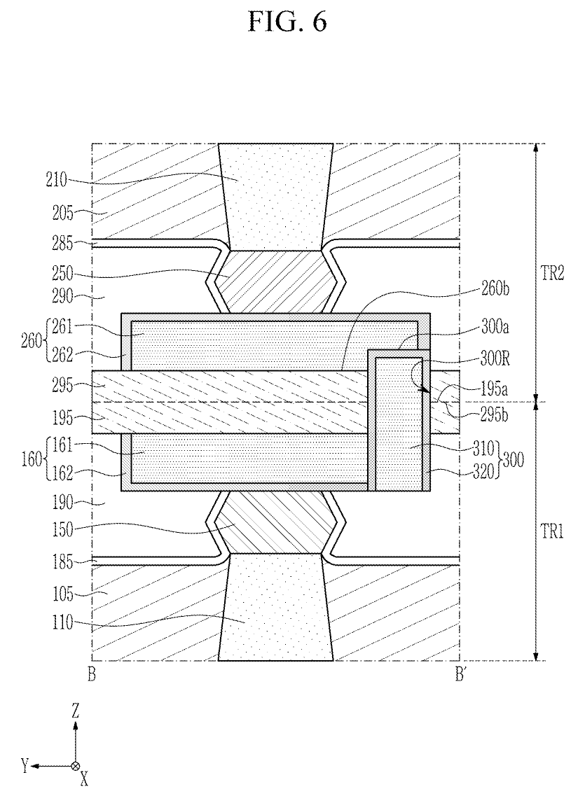

The first surface 300a of the connection structure 300 may be positioned at a lower level than the first surface of the upper contact structure 260. The first surface 300a of the connection structure 300 may be positioned closer to the first surface 195a of the lower bonding insulating layer 195 than to the first surface of the upper contact structure 260. The first surface 300a of the connection structure 300 may be positioned at substantially the same level as the second surface 260b of the upper contact structure 260, but example embodiments are not limited thereto. An explanation of this will be provided later with reference to FIG. 6.

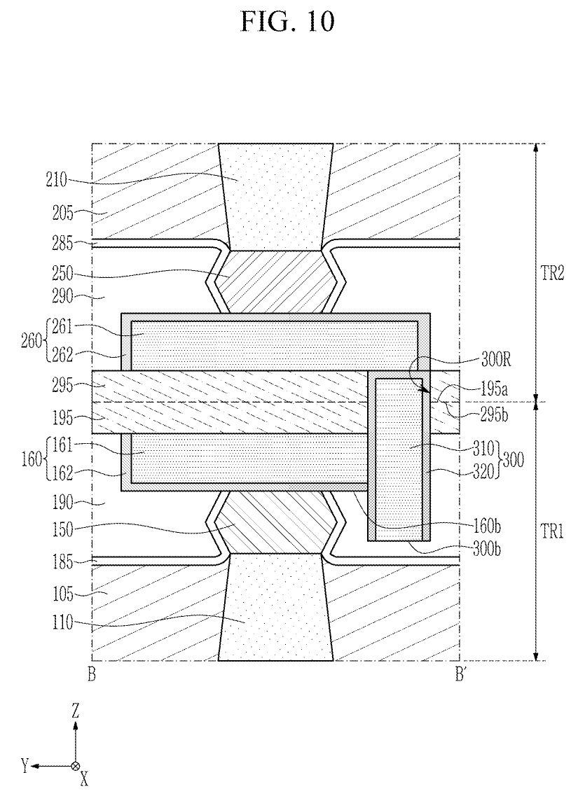

The second surface 300b of the connection structure 300 may be positioned at a lower level than the first surface of the lower contact structure 160. The second surface 300b of the connection structure 300 may be positioned further from the first surface 195a of the lower bonding insulating layer 195 than the first surface of the lower contact structure 160. The second surface 300b of the connection structure 300 may be positioned at substantially the same level as the second surface 160b of the lower contact structure 160, but example embodiments are not limited thereto. As another example, the second surface 300b of the connection structure 300 may be positioned at a higher or lower level than the second surface 160b of the lower contact structure 160. An explanation of this will be provided later with reference to FIG. 10.

A length of the connection structure 300 in the third direction (Z direction) may be greater than or equal to the distance between the lower contact structure 160 and the upper contact structure 260 in the third direction (Z direction). In other words, a length of the connection structure 300 along the third direction (Z direction) may be greater than or equal to the distance between the first surface of the lower contact structure 160 and the second surface 260b of the upper contact structure 260 along the third direction (Z direction). This may be due to the process characteristics of forming a connection recess 300R by removing at least a portion of the lower contact structure 160 after forming the lower contact structure 160 and the upper contact structure 260, and forming the connection structure 300 within the connection recess 300R. In this range, a length of the connection structure 300 in the third direction (Z direction) may be reduced, thereby preventing the occurrence of parasitic capacitance and improving the reliability of the semiconductor device.

In an embodiment, the connection structure 300 may be positioned spaced apart from the lower source/drain pattern 150 and the upper source/drain pattern 250. the connection structure 300 may be non-overlapping with the lower source/drain pattern 150 and the upper source/drain pattern 250.

For example, the connection structure 300 may be positioned spaced apart from the lower source/drain pattern 150 and the upper source/drain pattern 250 in the second direction (Y direction). Accordingly, the connection structure 300 may be non-overlapping with the lower source/drain pattern 150 and the upper source/drain pattern 250 in the third direction (Z direction), and may be overlapped with the lower interlayer insulating layer 190 and the upper interlayer insulating layer 290 in the third direction (Z direction). the connection structure 300 may completely overlap the lower interlayer insulating layer 190 and the upper interlayer insulating layer 290 in the third direction (Z direction), but example embodiments are not limited thereto. This may be due to the process characteristics of forming a connection recess 300R by removing at least a portion of the lower contact structure 160 after forming the lower contact structure 160 and the upper contact structure 260, and forming the connection structure 300 within the connection recess 300R. Accordingly, the lower source/drain pattern 150 and/or the upper source/drain pattern 250 may be prevented from being deteriorated during the process of forming the connection structure 300.

Additionally, the connection structure 300 may be positioned spaced apart from the upper source/drain pattern 250 in the third direction (Z direction). Accordingly, the connection structure 300 may be non-overlapping with the upper source/drain pattern 250 in the second direction (Y direction). The first surface 300a of the connection structure 300 may be positioned at a lower level than the lower surface of the upper source/drain pattern 250. That is, the first surface 300a of the connection structure 300 may be positioned closer to the first surface 195a of the lower bonding insulating layer 195 than to the lower surface of the upper source/drain pattern 250.

the connection structure 300 may be non-overlapping with the lower source/drain pattern 150 in the second direction (Y direction). The second surface 300b of the connection structure 300 may be positioned at a higher level than the lower surface of the lower source/drain pattern 150. The second surface 300b of the connection structure 300 may be positioned closer to the first surface 195a of the lower bonding insulating layer 195 than to the lower surface of the lower source/drain pattern 150. The second surface 300b of the connection structure 300 may be positioned at substantially the same level as the upper surface of the lower source/drain pattern 150. That is, the second surface 300b of the connection structure 300 and the upper surface of the lower source/drain pattern 150 may be positioned at substantially the same distance from the first surface 195a of the lower bonding insulating layer 195. However, it is not limited thereto, and as another example, the second surface 300b of the connection structure 300 may be positioned closer to the first surface 195a of the lower bonding insulating layer 195 than to the upper surface of the lower source/drain pattern 150. As another example, the second surface 300b of the connection structure 300 may be positioned further from the first surface 195a of the lower bonding insulating layer 195 than the upper surface of the lower source/drain pattern 150. At least a portion of the connection structure 300 may overlap the lower source/drain pattern 150 in the second direction (Y direction). An explanation of this will be provided later with reference to FIG. 10.

In summary, the connection structure 300 may be non-overlapping with the lower source/drain pattern 150 in the second direction (Y direction) and the third direction (Z direction), and may be non-overlapping with the upper source/drain pattern 250 in the second direction (Y direction) and the third direction (Z direction). Accordingly, a length of the connection structure 300 in the third direction (Z direction) may be smaller than or equal to the distance between the lower surface of the lower source/drain pattern 150 and the upper surface of the upper source/drain pattern 250 in the third direction (Z direction). Additionally, a length of the connection structure 300 in the third direction (Z direction) may be less than or equal to the distance between the upper surface of the lower source/drain pattern 150 and the lower surface of the upper source/drain pattern 250 in the third direction (Z direction). That is, a length of the connection structure 300 in the third direction (Z direction) may be smaller than or equal to the distance between the second surface 160b of the lower contact structure 160 and the first surface of the upper contact structure 260. This may be due to the process characteristics of forming a connection recess 300R by removing at least a portion of the lower contact structure 160 after forming the lower contact structure 160 and the upper contact structure 260, and forming the connection structure 300 within the connection recess 300R. In this range, a length of the connection structure 300 in the third direction (Z direction) may be reduced, thereby preventing the occurrence of parasitic capacitance and improving the reliability of the semiconductor device.

the connection structure 300 may include a first connection electrode 310 and a second connection electrode 320 surrounding at least a portion of the first connection electrode 310.

The second connection electrode 320 may be positioned within the connection recess 300R. The second connection electrode 320 may be conformally positioned on the bottom surface and inner wall of the connection recess 300R. The second connection electrode 320 may be positioned on the upper surface and side surface of the first connection electrode 310. The second connection electrode 320 may cover the upper surface and side surface of the first connection electrode 310.

The second connection electrode 320 may be positioned between the first connection electrode 310 and the lower contact structure 160, between the first connection electrode 310 and the lower interlayer insulating layer 190, between the first connection electrode 310 and the lower bonding insulating layer 195, between the first connection electrode 310 and the upper bonding insulating layer 295, and between the first connection electrode 310 and the upper contact structure 260.

The second connection electrode 320 may be in contact with the side surface of the lower contact structure 160. For example, the second connection electrode 320 may be in contact with the first lower contact electrode 161 and the second lower contact electrode 162 of the lower contact structure 160. Additionally, the second connection electrode 320 may come into contact with the second surface 260b of the upper contact structure 260. For example, the second connection electrode 320 may be in contact with the first upper contact electrode 261 and the second upper contact electrode 262 of the upper contact structure 260.

The second connection electrode 320 may include a conductive material. The second connection electrode 320 may include the same material as the second upper contact electrode 262 and the second lower contact electrode 162. For example, the second connection electrode 320 may include at least one of a metal, a metal alloy, a conductive metal nitride, a conductive metal carbide, a conductive metal oxide, a conductive metal carbonitride, and a two-dimensional (2D) material. For example, the second connection electrode 320 may include, but example embodiments are not limited thereto, titanium nitride (TiN). As another example, the second connection electrode 320 may include at least one metal silicide film.

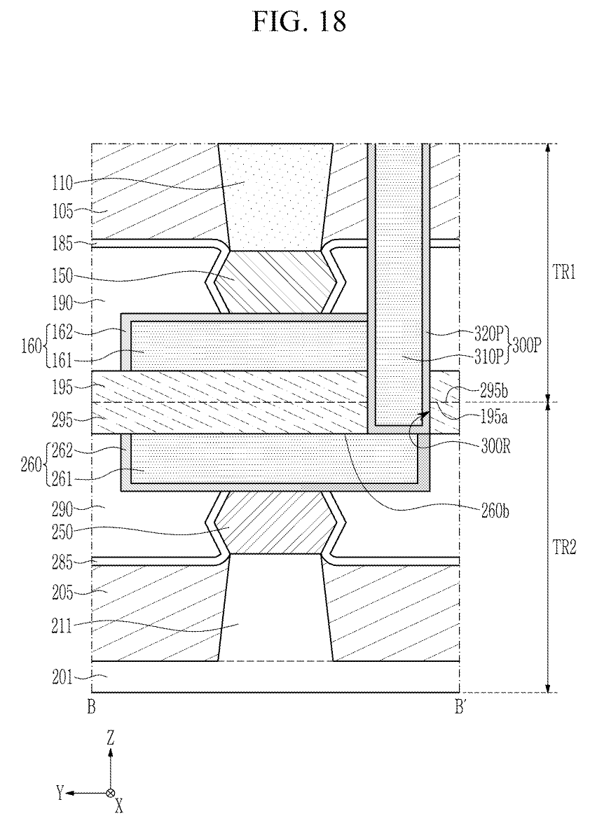

The first connection electrode 310 may fill the remaining portion of the connection recess 300R where the second connection electrode 320 is formed. The first connection electrode 310 may be in contact with the lower interlayer insulating layer 190. For example, the lower surface of the first connection electrode 310 may be in contact with the lower interlayer insulating layer 190. This may be due to the process characteristics of forming the first connection electrode material layer (see 310P of FIG. 18) and the second connection electrode material layer (see 320P of FIG. 18) during the process of forming the connection structure 300, and then removing at least a portion of the first connection electrode material layer (see 310P of FIG. 18) and the second connection electrode material layer (see 320P of FIG. 18) to form the first connection electrode 310 and the second connection electrode 320.

The first connection electrode 310 may include a conductive material. The first connection electrode 310 may include the same material as the first upper contact electrode 261 and the first lower contact electrode 161. For example, the first connection electrode 310 may include at least one of a metal, a metal alloy, a conductive metal nitride, a conductive metal carbide, a conductive metal oxide, a conductive metal carbonitride, and a two-dimensional (2D) material. For example, the first connection electrode 310 may include, but example embodiments are not limited thereto, tungsten (W), molybdenum (Mo), or a combination thereof.

According to an embodiment, a semiconductor device may include a first transistor structure TR1 and a second transistor structure TR2 that are connected to each other. In order to connect the lower source/drain pattern 150 of the first transistor structure TR1 and the upper source/drain pattern 250 of the second transistor structure TR2, the semiconductor device may include a lower contact structure 160 and an upper contact structure 260 positioned between the lower source/drain pattern 150 and the upper source/drain pattern 250, and a connection structure 300 connecting between the lower contact structure 160 and the upper contact structure 260. As the lower contact structure 160 and the upper contact structure 260 are positioned between the lower source/drain pattern 150 and the upper source/drain pattern 250, the distance between the lower contact structure 160 and the upper contact structure 260 in the third direction (Z direction) may be reduced, and a length of the connection structure 300 in the third direction (Z direction) may be reduced. Accordingly, the semiconductor device may prevent parasitic capacitance from occurring due to the connection structure 300, and improve the reliability of the semiconductor device.

Additionally, the connection structure 300 may be non-overlapping with the lower source/drain pattern 150 in the second direction (Y direction) and the third direction (Z direction), and may be non-overlapping with the upper source/drain pattern 250 in the second direction (Y direction) and the third direction (Z direction). Accordingly, the lower source/drain pattern 150 and/or the upper source/drain pattern 250 may be prevented from being deteriorated during the process of forming the connection structure 300.

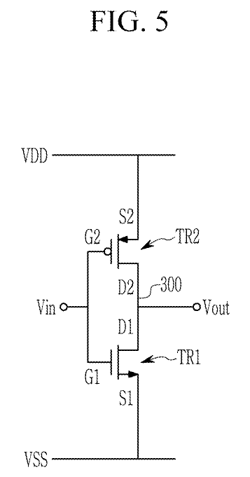

Hereinafter, a semiconductor device according to an embodiment will be described with reference to FIG. 5.

FIG. 5 is a circuit diagram showing an application example of a semiconductor device according to an embodiment.

Referring to FIG. 5, a first transistor structure TR1 and a second transistor structure TR2 of a semiconductor device according to an embodiment may be connected to each other by a connection structure 300. The first transistor structure TR1 may have a first conductivity type, and the second transistor structure TR2 may have a second conductivity type.

The first transistor structure TR1 may include a source electrode S1, a drain electrode D1, and a gate electrode G1. The drain electrode D1 of the first transistor structure TR1 may be connected to the drain electrode D2 of the second transistor structure TR2. The gate electrode G1 of the first transistor structure TR1 may be connected to the gate electrode G2 of the second transistor structure TR2. Additionally, an input signal Vin may be applied to a gate electrode G1 of the first transistor structure TR1, and a first power supply voltage VSS may be applied to a source electrode S1 of the first transistor structure TR1. The first power supply voltage VSS may be, for example, ground voltage.

The second transistor structure TR2 may include a source electrode S2, a drain electrode D2, and a gate electrode G2. The drain electrode D2 of the second transistor structure TR2 may be connected to the drain electrode D1 of the first transistor structure TR2. The gate electrode G2 of the second transistor structure TR2 may be connected to the gate electrode G1 of the first transistor structure TR1. Additionally, an input signal Vin may be applied to a gate electrode G2 of the second transistor structure TR2, and a second power supply voltage VDD may be applied to a source electrode S2 of the second transistor structure TR2. The second power supply voltage VDD may be, for example, greater than the first power supply voltage VSS.

In the embodiment of FIG. 5, the source electrode S1 and the drain electrode D1 of the first transistor structure TR1 may correspond to the lower source/drain pattern 150 of the embodiments of FIGS. 1 to 4, and the gate electrode G1 of the first transistor structure TR1 may correspond to the lower gate electrode 120 of the embodiments of FIGS. 1 to 4. Additionally, the source electrode S2 and the drain electrode D2 of the second transistor structure TR2 may correspond to the upper source/drain pattern 250 of the embodiments of FIGS. 1 to 4, and the gate electrode G2 of the second transistor structure TR2 may correspond to the upper gate electrode 220 of the embodiments of FIGS. 1 to 4.

According to an embodiment, a semiconductor device may have an input signal Vin applied to a gate electrode G1 of a first transistor structure TR1 and a gate electrode G2 of a second transistor structure TR2. In this case, since the drain electrode D1 of the first transistor structure TR1 and the drain electrode D2 of the second transistor structure TR2 are connected to each other by the connection structure 300, the output signal (Vout) may be output to the drain electrode D1 of the first transistor structure TR1 and the drain electrode D2 of the second transistor structure TR2, and accordingly, the semiconductor element may perform the function of a CMOS inverter.

Hereinafter, a laminated structure of a semiconductor device according to some embodiments will be described with reference to FIGS. 6 to 12.

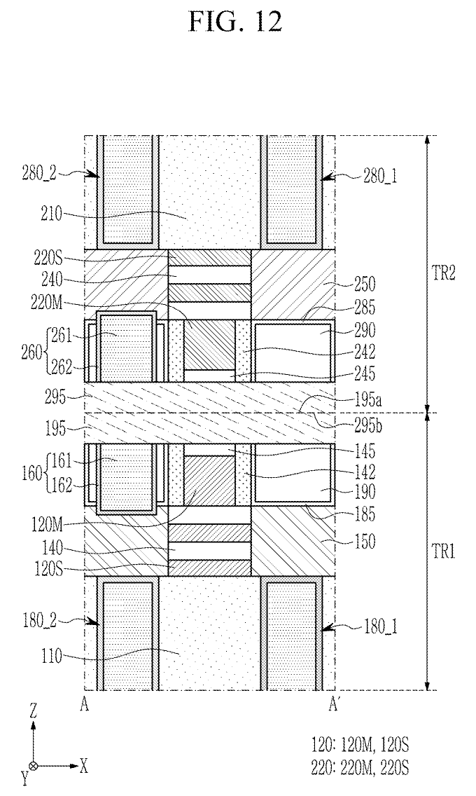

FIGS. 6, 7, 8, 9, 10, and 11 are cross-sectional views corresponding to B-B' of FIG. 1, illustrating semiconductor devices according to some embodiments. FIG. 12 is a cross-sectional view corresponding to A-A' of FIG. 1, illustrating a semiconductor device according to some embodiments.

The embodiments illustrated in FIGS. 6 to 12 are substantially identical to the embodiments illustrated in FIGS. 1 to 4, so a description thereof will be omitted and the differences will be mainly explained.

Referring to FIG. 6, a connection structure 300 of a semiconductor device according to some embodiments may be positioned within an upper contact structure 260. the connection structure 300 may include a portion that overlaps the upper contact structure 260 in the second direction (Y direction). At least a portion of the connection structure 300 may be embedded within the upper contact structure 260. The first surface 300a and part of the side surface of the connection structure 300 may be surrounded by the upper contact structure 260. Accordingly, the bonding area of the connection structure 300 and the upper contact structure 260 may increase. At least a portion of the connection structure 300 may overlap the upper contact structure 260 in the second direction (Y direction). The first surface 300a of the connection structure 300 may be positioned at a higher level than the second surface 260b of the upper contact structure 260. That is, the first surface 300a of the connection structure 300 may be positioned further from the first surface 195a of the lower bonding insulating layer 195 than the second surface 260b of the upper contact structure 260.

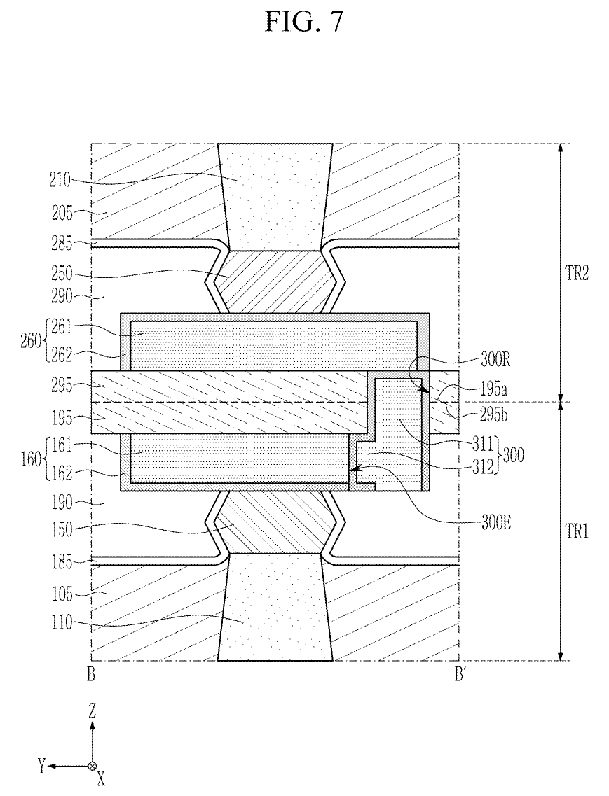

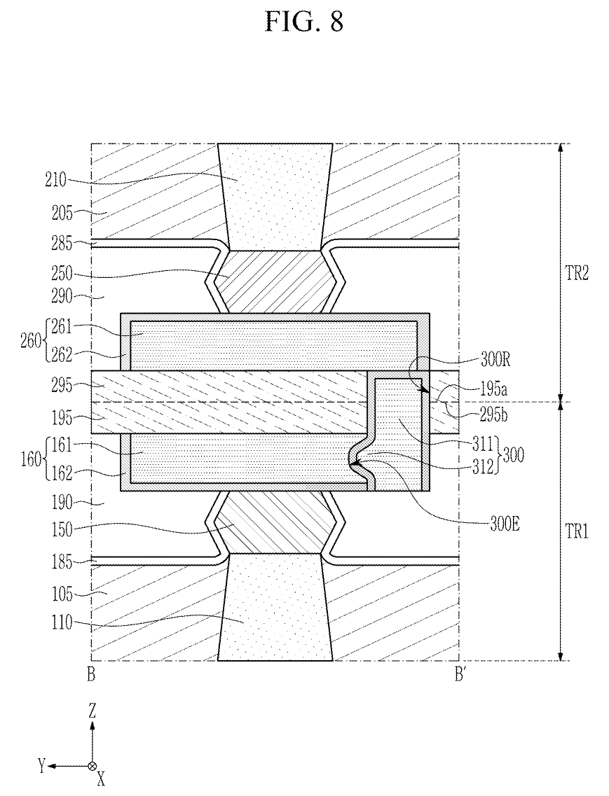

Referring to FIGS. 7 and 8, a connection structure 300 of a semiconductor device according to some embodiments may include an extension portion 311 extending in a third direction (Z direction) and a protrusion portion 312 protruding in a second direction (Y direction) toward a lower contact structure 160.

The extension portion 311 may extend in the third direction (Z direction) through the upper bonding insulating layer 295 and the lower bonding insulating layer 195. The extension portion 311 may be connected to the upper contact structure 260. The upper surface of the extension portion 311 may come into contact with the upper contact structure 260.

The protrusion portion 312 may protrude in a second direction (Y direction) from one side of the extension portion 311. The protrusion portion 312 may be positioned within a recess 300E positioned within the lower contact structure 160. The recess 300E may be defined by the lower contact structure 160. The protrusion portion 312 may be non-overlapping with the lower source/drain pattern 150 and the upper source/drain pattern 250 in the third direction (Z direction). A side surface of the protrusion portion 312 may have various shapes. For example, as illustrated in FIG. 7, the side surface of the protrusion portion 312 may extend in a third direction (Z direction). As another example, as illustrated in FIG. 8, the side surface of the protrusion portion 312 may have a convex curved shape toward the lower contact structure 160.

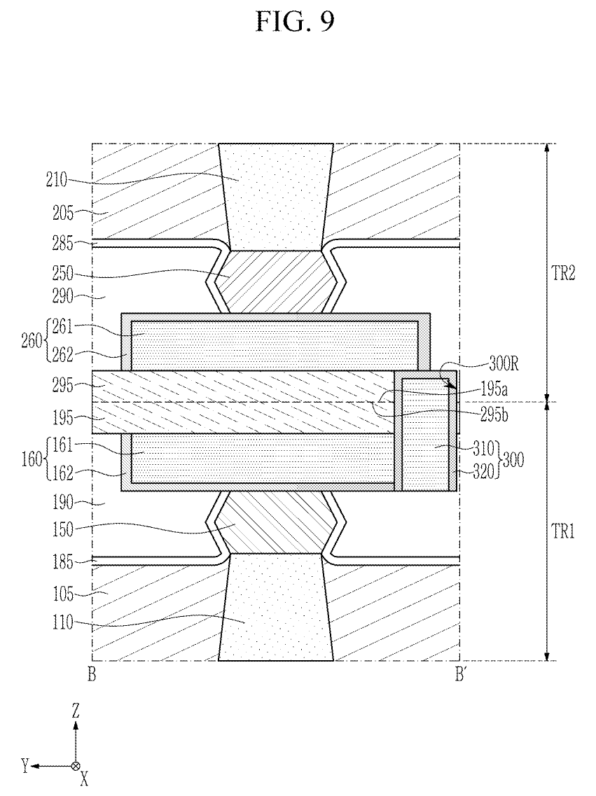

Referring to FIG. 9, a portion of a connection structure 300 of a semiconductor device according to some embodiments may be non-overlapping with an upper contact structure 260 in a third direction (Z direction). For example, a portion of the connection structure 300 may overlap with the upper contact structure 260 in the third direction (Z direction), and the remaining portion may not overlap with the upper contact structure 260 in the third direction (Z direction). The remaining portion of the connection structure 300 may overlap the upper interlayer insulating layer 290 in the third direction (Z direction). A portion of the connection structure 300 may be in contact with the upper contact structure 260, and the remaining portion may be in contact with the upper interlayer insulating layer 290.

Referring to FIG. 10, a connection structure 300 of a semiconductor device according to some embodiments may overlap a lower source/drain pattern 150 in a second direction (Y direction). For example, the connection structure 300 may extend further from the second surface 160b of the lower contact structure 160 toward the lower pattern 110. The second surface 300b of the connection structure 300 may be positioned at a lower level than the second surface 160b of the lower contact structure 160. That is, the second surface 300b of the connection structure 300 may be positioned further from the first surface 195a of the lower bonding insulating layer 195 than the second surface 160b of the lower contact structure 160. Accordingly, the second surface 300b of the connection structure 300 may be positioned further from the first surface 195a of the lower bonding insulating layer 195 than the upper surface of the lower source/drain pattern 150. However, even in this case, the second surface 300b of the connection structure 300 may be positioned closer to the first surface 195a of the lower bonding insulating layer 195 than to the lower surface of the lower source/drain pattern 150.

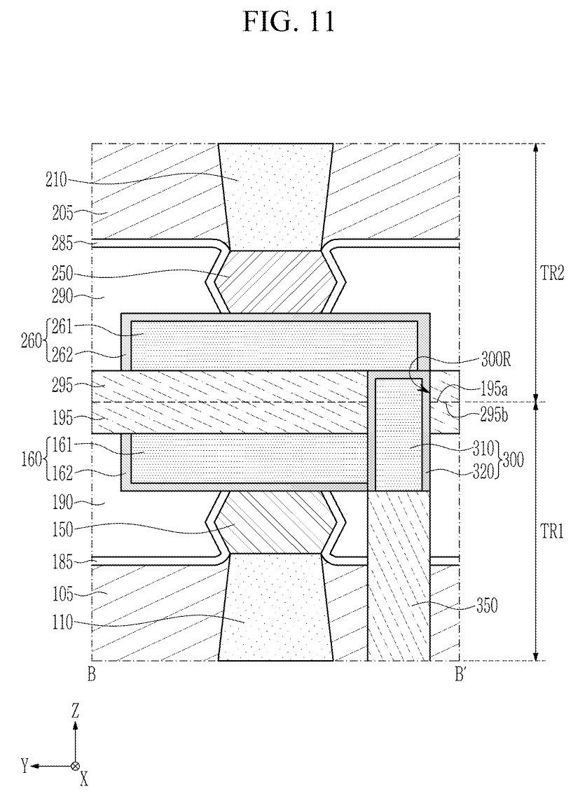

Referring to FIG. 11, a semiconductor device according to some embodiments may further include an insulating pattern 350 positioned on a second surface 300b of a connection structure 300.

The insulating pattern 350 may extend in the third direction (Z direction). The insulating pattern 350 may penetrate the lower interlayer insulating layer 190, the first etch stop layer 185, and the lower field insulating layer 105. The insulating pattern 350 may overlap the connection structure 300 in the third direction (Z direction). The insulating pattern 350 may overlap the lower source/drain pattern 150 and the lower pattern 110 in the second direction (Y direction). The insulating pattern 350 may be a pattern formed by forming a connection structure material layer (see 300P of FIG. 18) in a connection recess 300R during the process of forming a connection structure 300, removing at least a portion of the connection structure material layer (see 300 of FIG. 18), and then forming an insulating material layer in the removed space.

The insulating pattern 350 may include various insulating materials. The insulating pattern 350 may include the same material as the lower interlayer insulating layer 190 and the lower field insulating layer 105, but is not limited thereto, and may include a material different from the lower interlayer insulating layer 190 and the lower field insulating layer 105. For example, the insulating pattern 350 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

Referring to FIG. 12, a semiconductor device according to some embodiments may include a plurality of lower penetrating structures 180_1, 180_2 and a plurality of upper penetrating structures 280_1, 280_2. For example, a semiconductor device according to some embodiments may include a first lower penetrating structure 180_1 connected to a lower source/drain pattern 150 that is not connected to a lower contact structure 160 and a second lower penetrating structure 180_2 connected to a lower source/drain pattern 150 that is connected to the lower contact structure 160. Additionally, the semiconductor device according to some embodiments may include a first upper penetrating structure 280_1 connected to an upper source/drain pattern 250 that is not connected to an upper contact structure 260 and a second upper penetrating structure 280_2 connected to an upper source/drain pattern 250 that is connected to an upper contact structure 260.

However, this is merely exemplary, and the plurality of lower penetrating structures 180_1, 180_2 may be connected to at least one of the plurality of lower source/drain patterns 150, and the plurality of upper penetrating structures 280_1, 280_2 may be connected to at least one of the plurality of upper source/drain patterns 250.

Hereinafter, a method for manufacturing a semiconductor device according to an embodiment will be described with reference to FIGS. 13 to 22.

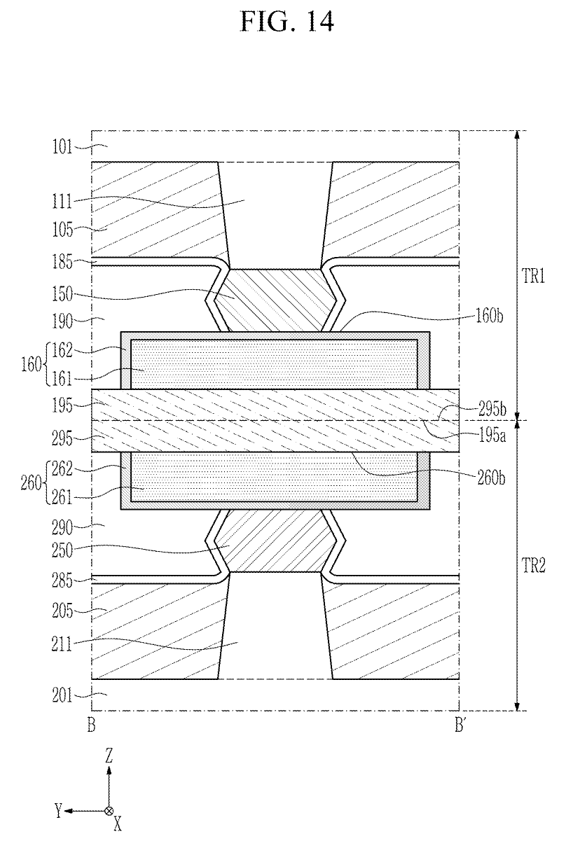

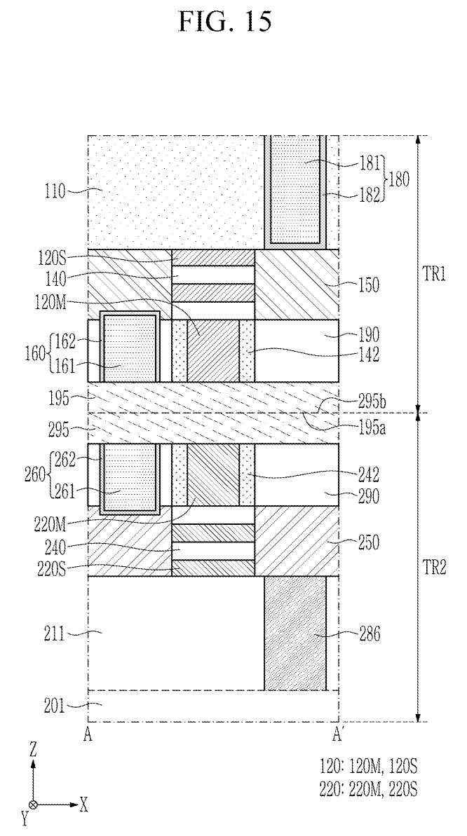

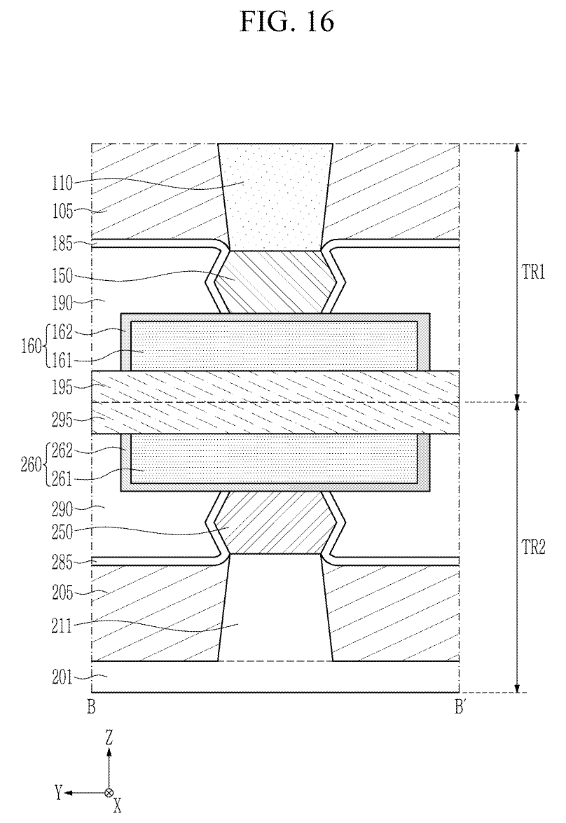

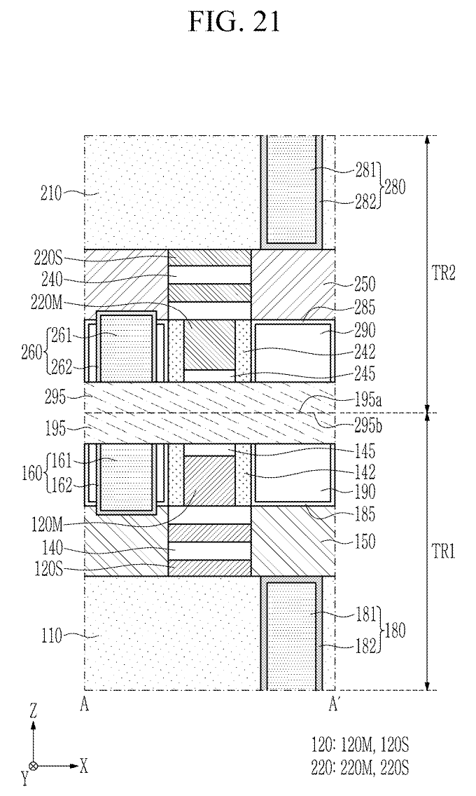

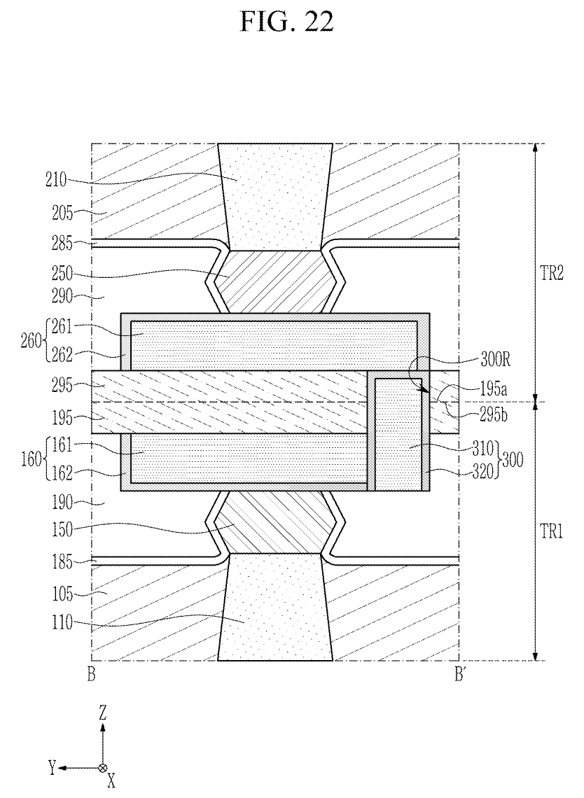

FIG. 13 is a cross-sectional view corresponding to A-A' of FIG. 1, showing an intermediate step of a method for manufacturing a semiconductor device according to an embodiment. FIG. 14 is a cross-sectional view corresponding to B-B' of FIG. 1, showing an intermediate step of a method for manufacturing a semiconductor device according to an embodiment. FIG. 15 is a cross-sectional view corresponding to A-A' of FIG. 1, showing an intermediate step of a method for manufacturing a semiconductor device according to an embodiment. FIGS. 16, 17, 18, 19, and 20 are cross-sectional views corresponding to B-B' of FIG. 1, showing intermediate steps of a method for manufacturing a semiconductor device according to an embodiment. FIG. 21 is a cross-sectional view corresponding to A-A' of FIG. 1, showing an intermediate step of a method for manufacturing a semiconductor device according to an embodiment. FIG. 22 is a cross-sectional view corresponding to B-B' of FIG. 1, showing an intermediate step of a method for manufacturing a semiconductor device according to an embodiment.

As illustrated in FIG. 13 and FIG. 14, a second transistor structure TR2 and a first transistor structure TR1 may be formed, and the first transistor structure TR1 may be bonded on the second transistor structure TR2.

A second transistor structure TR2 may include a second substrate 201, upper channel patterns 240 positioned on the second substrate 201, an upper source/drain pattern 250 positioned on opposite sides of the upper channel patterns 240 along the first direction (X direction), an upper gate electrode 220 surrounding the upper channel patterns 240, an upper bonding insulating layer 295 positioned on the upper source/drain pattern 250, and an upper contact structure 260 positioned between the upper bonding insulating layer 295 and the upper source/drain pattern 250.

The second substrate 201 may be SOI (silicon-on-insulator) or bulk silicon. Alternatively, the second substrate 201 may be a silicon substrate, or may include other materials, such as, but not limited to, silicon germanium (SiGe), SGOI (silicon germanium on insulator), indium antimonide, lead tellurium compound, indium arsenide, indium phosphide, gallium arsenide, or gallium antimonide. The upper contact structure 260 may extend in the second direction (Y direction).

The second transistor structure TR2 may further include an upper active pattern 211 positioned between the second substrate 201 and the upper channel patterns 240 and between the second substrate 201 and the upper source/drain pattern 250. The second transistor structure TR2 may further include an upper field insulating layer 205 positioned on the second substrate 201. The upper field insulating layer 205 may be positioned on opposite sides of the upper channel patterns 240 in the second direction (Y direction).

The second transistor structure TR2 may further include an upper dummy source/drain pattern 286 positioned on a lower surface of the upper source/drain pattern 250. The upper dummy source/drain pattern 286 may be positioned on the second substrate 201. The upper dummy source/drain pattern 286 may be in contact with the upper source/drain pattern 250. The second transistor structure TR2 may further include an upper interlayer insulating layer 290 positioned between the upper source/drain pattern 250 and the upper bonding insulating layer 295. The upper interlayer insulating layer 290 may be penetrated by the upper contact structure 260. The remaining parts of the description of each component of the second transistor structure TR2 may correspond to the description of each component of the second transistor structure TR2 of the embodiments of FIGS. 1 to 4.

The first transistor structure TR1 may include a lower bonding insulating layer 195 positioned on an upper bonding insulating layer 295, lower channel patterns 140 positioned on the lower bonding insulating layer 195, a lower source/drain pattern 150 positioned on the lower bonding insulating layer 195 and on opposite sides of the lower channel patterns 140 along a first direction (X direction), a lower gate electrode 120 surrounding the lower channel patterns 140, and a lower contact structure 160 positioned between the lower source/drain pattern 150 and the lower bonding insulating layer 195.

The lower contact structure 160 may extend in the second direction (Y direction). The lower contact structure 160 may extend parallel to the upper contact structure 260.

The first transistor structure TR1 may further include a lower active pattern 111 positioned on a lower source/drain pattern 150 and a lower gate electrode 120. The lower active pattern 111 may include the same material as the upper active pattern 211, but example embodiments are not limited thereto.

The first transistor structure TR1 may further include a first substrate 101 positioned on the lower active pattern 111. The first substrate 101 may be SOI (silicon-on-insulator) or bulk silicon. Alternatively, the first substrate 101 may be a silicon substrate, or may include other materials, such as, but not limited to, silicon germanium (SiGe), silicon germanium on insulator (SGOI), indium antimonide, lead tellurium compound, indium arsenide, indium phosphide, gallium arsenide, or gallium antimonide. The upper contact structure 260 may extend in the second direction (Y direction).

The first transistor structure TR1 may further include a lower interlayer insulating layer 190 positioned between the lower source/drain pattern 150 and the lower bonding insulating layer 195. The lower interlayer insulating layer 190 may be penetrated by the lower contact structure 160.

The first transistor structure TR1 may further include a lower dummy source/drain pattern 186 positioned on the lower source/drain pattern 150. The lower dummy source/drain pattern 186 may be positioned between the lower source/drain pattern 150 and the first substrate 101. The lower dummy source/drain pattern 186 may be in contact with the lower source/drain pattern 150.

The first transistor structure TR1 may further include a lower field insulating layer 105 positioned on the lower interlayer insulating layer 190. The lower field insulating layer 105 may be positioned between the lower interlayer insulating layer 190 and the first substrate 101. The lower field insulating layer 105 may be positioned on opposite sides of the lower channel patterns 140 in the second direction (Y direction). The remaining description of each component of the first transistor structure TR1 may correspond to the description of each component of the first transistor structure TR1 of the embodiments of FIGS. 1 to 4.

A first transistor structure TR1 and a second transistor structure TR2 may be bonded together. The upper bonding insulating layer 295 of the second transistor structure TR2 and the lower bonding insulating layer 195 of the first transistor structure TR1 may be bonded. Accordingly, the second surface 295b of the upper bonding insulating layer 295 and the first surface 195a of the lower bonding insulating layer 195 may form a bonding interface.

As shown in FIG. 15 and FIG. 16, the first substrate 101 and the lower active pattern 111 may be removed, the lower pattern 110 may be formed, and after removing the lower dummy source/drain pattern 186, the lower penetrating structure 180 may be formed in the removed space.

First, the first substrate 101 and the lower active pattern 111 may be removed, and the lower pattern 110 may be formed. The process of removing the first substrate 101 and the lower active pattern 111 may be performed using chemical mechanical polishing and wet etching methods, but example embodiments are not limited thereto. A lower pattern 110 may be formed within the space from which the lower active pattern 111 has been removed. The lower pattern 110 may include various insulating materials. For example, the lower pattern 110 may include, but example embodiments are not limited thereto, silicon oxide (SiO₂). Accordingly, the upper surface of the lower dummy source/drain pattern 186 may be exposed.

Next, the exposed lower dummy source/drain pattern 186 may be removed. The process of removing the lower dummy source/drain pattern 186 may be performed using a wet etching method or a dry etching method, but example embodiments are not limited thereto. Accordingly, the lower source/drain pattern 150 may be exposed.

Next, a lower penetrating structure 180 may be formed within the space from which the lower dummy source/drain pattern 186 has been removed. A second lower through-via 182 and a first lower through-via 181 may be sequentially formed within the space where the lower dummy source/drain pattern 186 has been removed to form a lower penetrating structure 180. The first lower through-via 181 and the second lower through-via 182 may include a conductive material. The first lower through-via 181 and the second lower through-via 182 may include at least one of, for example, a metal, a metal alloy, a conductive metal nitride, a conductive metal carbide, a conductive metal oxide, a conductive metal carbonitride, and a two-dimensional (2D) material. The lower penetrating structure 180 may be in contact with the lower source/drain pattern 150. The lower penetrating structure 180 may be connected to the lower source/drain pattern 150.

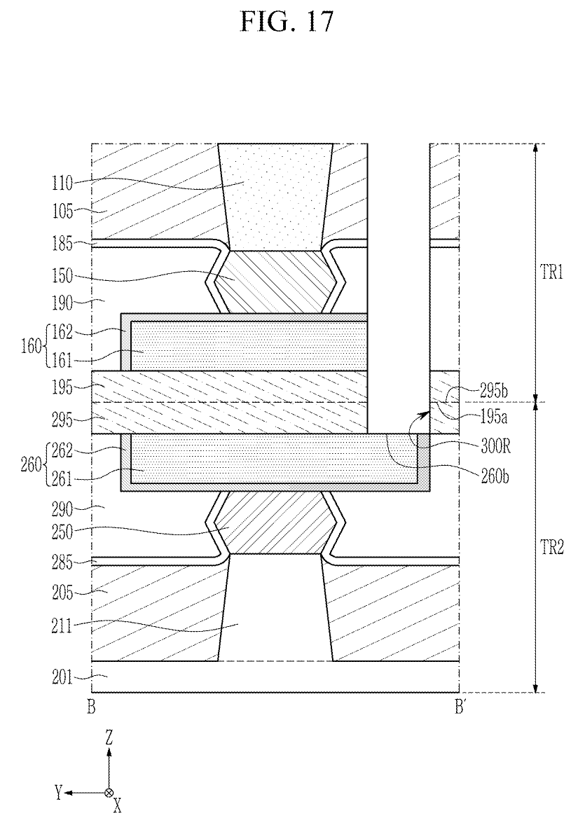

As illustrated in FIG. 17, the lower field insulating layer 105, the lower interlayer insulating layer 190, the lower contact structure 160, the lower bonding insulating layer 195, and the upper bonding insulating layer 295 may be patterned to form a connection recess 300R.

Specifically, the lower field insulating layer 105, the second etch stop layer 285, and the lower interlayer insulating layer 190 may be patterned first to expose the lower contact structure 160. The process of patterning the lower field insulating layer 105, the second etch stop layer 285, and the lower interlayer insulating layer 190 may be performed using a dry etching method, but example embodiments are not limited thereto. Next, at least a portion of the exposed lower contact structure 160 may be etched to expose the lower bonding insulating layer 195. At least a portion of the lower contact structure 160 may be etched using a material having an etching selectivity with respect to the lower field insulating layer 105, the second etch stop layer 285, and the lower interlayer insulating layer 190. Accordingly, during the etching process of at least a portion of the lower contact structure 160, the lower field insulating layer 105, the second etch stop layer 285, and the lower interlayer insulating layer 190 may not be etched. Finally, the exposed lower bonding insulating layer 195 and upper bonding insulating layer 295 may be sequentially patterned to form a connection recess 300R. The connection recess 300R may extend in the third direction (Z direction).

The inner wall of the connection recess 300R may be defined by the upper bonding insulating layer 295, the lower bonding insulating layer 195, the lower contact structure 160, and the lower interlayer insulating layer 190. For example, one side wall along the second direction (Y direction) of the connection recess 300R may be defined by the upper bonding insulating layer 295, the lower bonding insulating layer 195, and the lower contact structure 160, and the other side wall opposite to the one side wall of the connection recess 300R may be defined by the upper bonding insulating layer 295, the lower bonding insulating layer 195, the lower contact structure 160, and the lower interlayer insulating layer 190. The bottom surface of the connection recess 300R may be defined by the upper contact structure 260.

The second surface 260b of the upper contact structure 260 may be exposed by the connection recess 300R. A side surface of the lower contact structure 160 may be exposed by the connection recess 300R. The connection recess 300R may be non-overlapping with the upper source/drain pattern 250 in the second direction (Y direction). The connection recess 300R may be non-overlapping with the upper source/drain pattern 250 and the lower source/drain pattern 150 in the third direction (Z direction).

As the connection recess 300R is formed, a length of the lower contact structure 160 along the second direction (Y direction) may be different from a length of the upper contact structure 260 along the second direction (Y direction). For example, a length of the lower contact structure 160 along the second direction (Y direction) may be shorter than a length of the upper contact structure 260 along the second direction (Y direction).

In some embodiments, at least a portion of the upper contact structure 260 may be removed together with the process of forming the connection recess 300R. That is, at least a portion of the connection recess 300R may be surrounded by the upper contact structure 260. In this case, the connection recess 300R may be formed within the upper contact structure 260.

As illustrated in FIG. 18, a connection structure material layer 300P may be formed within a connection recess 300R. First, a second connection electrode material layer 320P may be formed on the inner wall and bottom surface of the connection recess 300R. The second connection electrode material layer 320P may be conformally formed on the inner wall and bottom surface. The second connection electrode material layer 320P may include a conductive material. For example, the second connection electrode material layer 320P may include at least one of a metal, a metal alloy, a conductive metal nitride, a conductive metal carbide, a conductive metal oxide, a conductive metal carbonitride, and a two-dimensional (2D) material. For example, the second connection electrode material layer 320P may include, but example embodiments are not limited thereto, titanium nitride (TiN). As another example, the second connection electrode material layer 320P may include at least one metal silicide film.

Next, a first connection electrode material layer 310P may be formed on the second connection electrode material layer 320P to fill the connection recess 300R, thereby forming a connection structure material layer 300P. Accordingly, the second connection electrode material layer 320P may be positioned between the lower contact structure 160 and the first connection electrode material layer 310P and between the upper contact structure 260 and the first connection electrode material layer 310P. The first connection electrode material layer 310P may include a conductive material. For example, the first connection electrode material layer 310P may include at least one of a metal, a metal alloy, a conductive metal nitride, a conductive metal carbide, a conductive metal oxide, a conductive metal carbonitride, and a two-dimensional (2D) material. For example, the first connection electrode material layer 310P may include, but example embodiments are not limited thereto, tungsten (W), molybdenum (Mo), or a combination thereof.

the connection structure material layer 300P may extend in the third direction (Z direction). the connection structure material layer 300P may be non-overlapping with the upper source/drain pattern 250 in the second direction (Y direction). the connection structure material layer 300P may be non-overlapping with the upper source/drain pattern 250 and the lower source/drain pattern 150 in the third direction (Z direction).

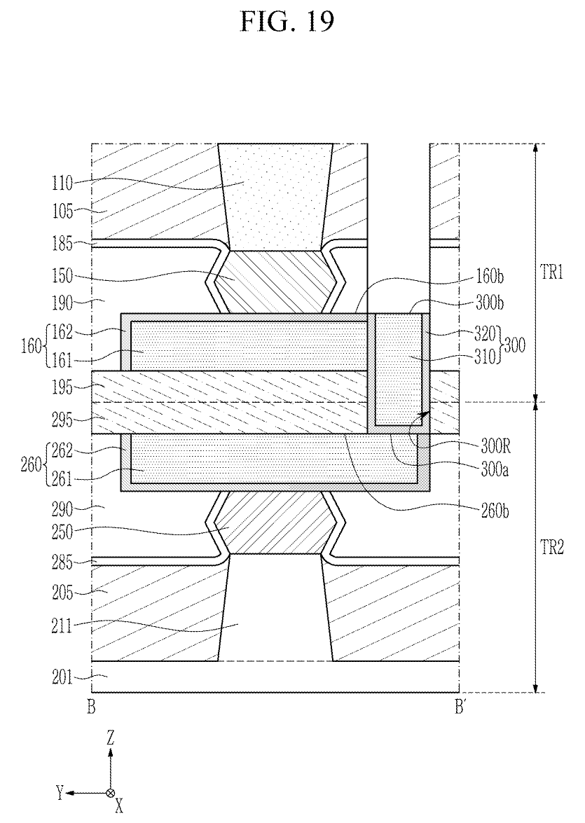

As illustrated in FIG. 19, a connection structure 300 may be formed by removing at least a portion of a connection structure material layer 300P. The connection structure 300 may be formed by removing a portion of the connection structure material layer 300P positioned at the upper portion of the connection recess 300R.

the connection structure 300 may be positioned between the lower interlayer insulating layer 190 and the upper contact structure 260. the connection structure 300 may be positioned on the second surface 260b of the upper contact structure 260. the connection structure 300 may be positioned on a side surface of the lower contact structure 160. the connection structure 300 may overlap the lower contact structure 160 in the first direction (X direction). the connection structure 300 may overlap the lower contact structure 160 in the second direction (Y direction). the connection structure 300 may be non-overlapping with the lower contact structure 160 in the third direction (Z direction), but example embodiments are not limited thereto. Additionally, the connection structure 300 may overlap the upper contact structure 260 in the third direction (Z direction). the connection structure 300 may be non-overlapping with the upper contact structure 260 in the second direction (Y direction), but example embodiments are not limited thereto.

the connection structure 300 may include a first surface 300a facing the upper source/drain pattern 250 and a second surface 300b opposite the first surface 300a. The second surface 300b of the connection structure 300 may be a surface facing the lower source/drain pattern 150. The first surface 300a of the connection structure 300 may correspond to the upper surface of the connection structure 300, and the second surface 300b of the connection structure 300 may correspond to the lower surface of the connection structure 300, but example embodiments are not limited thereto.

The first surface 300a of the connection structure 300 may be positioned closer to the first surface 195a of the lower bonding insulating layer 195 than to the first surface of the upper contact structure 260. The first surface 300a of the connection structure 300 and the second surface 260b of the upper contact structure 260 may be positioned at substantially the same distance from the first surface 195a of the lower bonding insulating layer 195. The second surface 300b of the connection structure 300 may be positioned further from the first surface 195a of the lower bonding insulating layer 195 than the first surface of the lower contact structure 160. The second surface 300b of the connection structure 300 and the second surface 160b of the lower contact structure 160 may be positioned at substantially the same distance from the first surface 195a of the lower bonding insulating layer 195, but are not limited thereto. For example, when the connection structure material layer 300P is less removed, as in the embodiment of FIG. 10, the second surface 300b of the connection structure 300 may be positioned further from the first surface 195a of the lower bonding insulating layer 195 than the second surface 160b of the lower contact structure 160.

A length of the connection structure 300 in the third direction (Z direction) may be less than or equal to the distance between the second surface 160b of the lower contact structure 160 and the first surface of the upper contact structure 260. A length of the connection structure 300 in the third direction (Z direction) may be greater than or equal to the distance between the lower contact structure 160 and the upper contact structure 260 in the third direction (Z direction). In other words, a length of the connection structure 300 along the third direction (Z direction) may be greater than or equal to the distance between the first surface of the lower contact structure 160 and the second surface 260b of the upper contact structure 260 along the third direction (Z direction). In this range, a length of the connection structure 300 in the third direction (Z direction) may be reduced, thereby preventing the occurrence of parasitic capacitance and improving the reliability of the semiconductor device.

the connection structure 300 may be positioned spaced apart from the upper source/drain pattern 250 in the third direction (Z direction). the connection structure 300 may be positioned spaced apart from the lower source/drain pattern 150 and the upper source/drain pattern 250 in the second direction (Y direction). the connection structure 300 may be non-overlapping with the lower source/drain pattern 150 in the second direction (Y direction) and the third direction (Z direction), and may be non-overlapping with the upper source/drain pattern 250 in the second direction (Y direction) and the third direction (Z direction). Accordingly, a length of the connection structure 300 in the third direction (Z direction) may be smaller than the distance between the upper surface of the lower source/drain pattern 150 and the lower surface of the upper source/drain pattern 250 in the third direction (Z direction). For example, a length of the connection structure 300 in the third direction (Z direction) may be smaller than the distance between the lower surface of the lower source/drain pattern 150 and the upper surface of the upper source/drain pattern 250 in the third direction (Z direction). In this range, a length of the connection structure 300 in the third direction (Z direction) may be reduced, thereby preventing the occurrence of parasitic capacitance and improving the reliability of the semiconductor device.

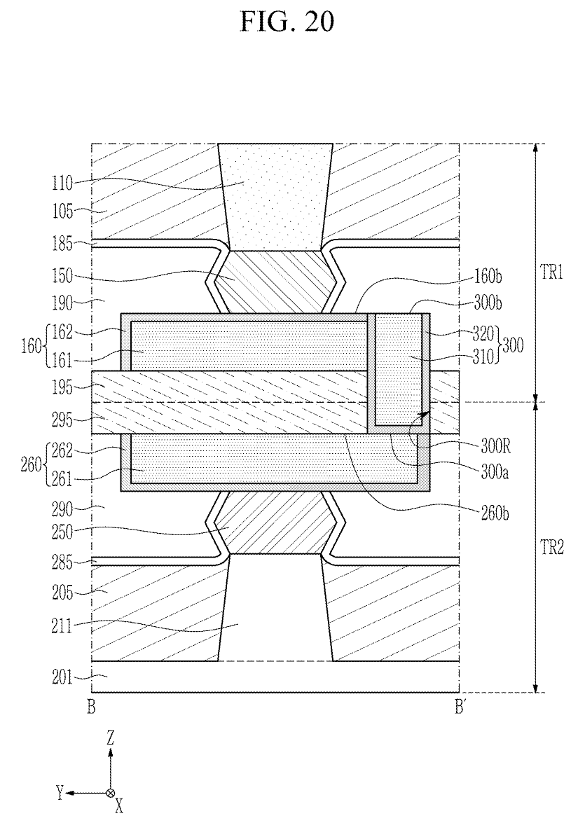

As illustrated in FIG. 20, a connection structure 300 may be formed and an insulating material may be filled into the remaining connection recess 300R. The insulating material may include the same material as the lower interlayer insulating layer 190 and the lower field insulating layer 105. Accordingly, a boundary may not be recognized between the insulating material and the lower interlayer insulating layer 190 and between the insulating material and the lower field insulating layer 105, but example embodiments are not limited thereto. For example, as illustrated in FIG. 11, a connection structure 300 may be formed and an insulating pattern (see 350 in FIG. 11) may be formed in the remaining connection recess 300R portion. The insulating pattern (see 350 in FIG. 11) may include a different material from the lower interlayer insulating layer 190 and the lower field insulating layer 105.

As illustrated in FIGS. 21 and 22, the semiconductor device may be flipped, the second substrate 201 and the upper active pattern 211 may be removed, the upper pattern 210 may be formed, and after removing the upper dummy source/drain pattern 286, the upper penetrating structure 280 may be formed in the removed space.

First, the second substrate 201 and the upper active pattern 211 may be removed, and the upper pattern 210 may be formed. The process of removing the second substrate 201 and the upper active pattern 211 may be performed using chemical mechanical polishing and wet etching methods, but example embodiments are not limited thereto. An upper pattern 210 may be formed within the space from which the upper active pattern 211 has been removed. The upper pattern 210 may include various insulating materials. For example, the upper pattern 210 may include, but example embodiments are not limited thereto, silicon oxide (SiO₂). Accordingly, the upper surface of the upper dummy source/drain pattern 286 may be exposed.

Next, the exposed upper dummy source/drain pattern 286 may be removed. The process of removing the upper dummy source/drain pattern 286 may be performed using a wet etching method or a dry etching method, but example embodiments are not limited thereto. Accordingly, the upper source/drain pattern 250 may be exposed.

Next, an upper penetrating structure 280 may be formed within the space from which the upper dummy source/drain pattern 286 has been removed. A second upper through-via 282 and a first upper through-via 281 may be sequentially formed in the space where the upper dummy source/drain pattern 286 has been removed to form an upper penetrating structure 280. The first upper through-via 281 and the second upper through-via 282 may include a conductive material. The first upper through-via 281 and the second upper through-via 282 may include at least one of, for example, a metal, a metal alloy, a conductive metal nitride, a conductive metal carbide, a conductive metal oxide, a conductive metal carbonitride, and a two-dimensional (2D) material. The upper penetrating structure 280 may be in contact with the upper source/drain pattern 250. The upper penetrating structure 280 may be connected to the upper source/drain pattern 250.

Accordingly, a semiconductor device according to an embodiment may be formed.

Although the embodiments have been described in detail above, the scope of the present disclosure is not limited thereto, and various modifications and improvements made by those skilled in the art using the basic concept of the present disclosure defined in the following claims also fall within the scope of the present disclosure.

### Description of symbols

110: Lower pattern

140: Lower channel patterns

150: Lower source/drain pattern

120: Lower gate electrode

160: Lower contact structure

180: Lower penetration structure

210: Upper pattern

240: Upper channel patterns

250: Upper source/drain pattern

220: Upper gate electrode

260: Upper contact structure

280: Upper penetration structure

295: Upper bonding insulation layer

300: Connection structure

What is claimed is:

1. A semiconductor device comprising:
a first transistor structure including:
lower channel patterns,
a lower source/drain pattern positioned on opposite sides of the lower channel patterns,
a lower gate electrode surrounding the lower channel patterns,
a lower bonding insulating layer positioned on the lower source/drain pattern and the lower gate electrode, and
a lower contact structure positioned between the lower bonding insulating layer and the lower source/drain pattern;
a second transistor structure including:
an upper bonding insulating layer positioned on the lower bonding insulating layer,
upper channel patterns positioned on the upper bonding insulating layer,
an upper source/drain pattern positioned on the upper bonding insulating layer and positioned on opposite sides of the upper channel patterns;
an upper gate electrode surrounding the upper channel patterns, and
an upper contact structure positioned between the upper bonding insulating layer and the upper source/drain pattern; and
a connection structure electrically connecting the lower contact structure and the upper contact structure by penetrating the lower bonding insulating layer and the upper bonding insulating layer.

2. The semiconductor device of claim 1,
wherein the connection structure is positioned on a side surface of the lower contact structure and on a first surface of the upper contact structure.

3. The semiconductor device of claim 1,
wherein the connection structure overlaps the lower contact structure in a first direction and overlaps the upper contact structure in a second direction intersecting the first direction.

4. The semiconductor device of claim 3,
wherein the lower contact structure and the upper contact structure extend in the first direction, and
a length of the lower contact structure along the first direction is different from a length of the upper contact structure along the first direction.

5. The semiconductor device of claim 3,
wherein the connection structure includes a portion overlapping the upper contact structure in the first direction.

6. The semiconductor device of claim 3,
the connection structure includes:
an extension portion extending in the second direction, and
a protrusion portion protruding in the first direction toward the lower contact structure.

7. The semiconductor device of claim 1,
wherein the connection structure includes a first surface facing the upper source/drain pattern and a second surface facing the lower source/drain pattern, and
the second surface of the connection structure is positioned closer to an upper surface of the lower bonding insulating layer than to a lower surface of the lower source/drain pattern.

8. The semiconductor device of claim 1,
wherein the connection structure does not overlap with the lower source/drain pattern and the upper source/drain pattern.

9. The semiconductor device of claim 1,
wherein the lower bonding insulating layer is in contact with the upper bonding insulating layer.

10. The semiconductor device of claim 1,
wherein a length of the connection structure is less than or equal to a distance between a lower surface of the lower source/drain pattern and an upper surface of the upper source/drain pattern.

11. The semiconductor device of claim 10,
wherein a length of the connection structure is greater than or equal to a distance between the lower contact structure and the upper contact structure.

12. The semiconductor device of claim 1,
wherein the connection structure includes:
a first connection electrode; and
a second connection electrode surrounding at least a portion of the first connection electrode; and
the second connection electrode is in contact with a side surface of the lower contact structure.

13. The semiconductor device of claim 12,
wherein the second connection electrode is positioned between the lower contact structure and the first connection electrode and between the upper contact structure and the first connection electrode.

14. The semiconductor device of claim 12, further comprising:
a lower interlayer insulating layer surrounding the lower source/drain pattern,
wherein the first connection electrode is in contact with the lower interlayer insulating layer.

15. A semiconductor device comprising:
a first transistor structure including:
lower channel patterns,
a lower source/drain pattern positioned on opposite sides of the lower channel patterns,
a lower gate electrode surrounding the lower channel patterns,
a lower interlayer insulating layer positioned on the lower source/drain pattern,
a lower bonding insulating layer positioned on the lower interlayer insulating layer and the lower gate electrode, and
a lower contact structure penetrating the lower interlayer insulating layer, connected to the lower source/drain pattern, and extending in a first direction;
a second transistor structure including
an upper bonding insulating layer positioned on the lower bonding insulating layer,
upper channel patterns positioned on the upper bonding insulating layer,
an upper interlayer insulating layer positioned on the upper bonding insulating layer,
an upper source/drain pattern positioned on the upper interlayer insulating layer and positioned on opposite sides of the upper channel patterns,
an upper gate electrode surrounding the upper channel patterns, and
an upper contact structure penetrating the upper interlayer insulating layer, connected to the upper source/drain pattern, and extending in the first direction; and
a connection structure extending in a second direction intersecting with the first direction, electrically connecting the lower contact structure and the upper contact structure, and overlapping the lower contact structure in the first direction and overlaps the upper contact structure in the second direction.

16. The semiconductor device of claim 15,
wherein the connection structure does not overlap the lower source/drain pattern and the upper source/drain pattern in the second direction.

17. The semiconductor device of claim 15,
wherein the connection structure does not overlap the lower source/drain pattern and the upper source/drain pattern in the first direction.

18. The semiconductor device of claim 15,
wherein a length of the lower contact structure along the first direction is different from a length of the upper contact structure along the first direction.

19. The semiconductor device of claim 15,
the connection structure includes:
a first connection electrode; and
a second connection electrode surrounding at least a portion of the first connection electrode;
wherein at least a portion of the first connection electrode is in contact with the lower interlayer insulating layer.

20. A semiconductor device comprising:
a first transistor structure including:
lower channel patterns,
a lower source/drain pattern positioned on opposite sides of the lower channel patterns,
a lower gate electrode surrounding the lower channel patterns,
a lower interlayer insulating layer positioned on the lower source/drain pattern,
a lower bonding insulating layer positioned on the lower interlayer insulating layer and the lower gate electrode, and
a lower contact structure penetrating the lower interlayer insulating layer and connected to the lower source/drain pattern;
a second transistor structure including:
an upper bonding insulating layer positioned on the lower bonding insulating layer,
upper channel patterns positioned on the upper bonding insulating layer,
an upper interlayer insulating layer positioned on the upper bonding insulating layer,
an upper source/drain pattern positioned on the upper interlayer insulating layer and positioned on opposite sides of the upper channel patterns;
an upper gate electrode surrounding the upper channel patterns, and
an upper contact structure penetrating the upper interlayer insulating layer and connected to the upper source/drain pattern; and
a connection structure,
electrically connecting the lower contact structure and the upper contact structure,
wherein a length of the connection structure is less than or equal to a distance between a lower surface of the lower source/drain pattern and an upper surface of the upper source/drain pattern.
